(19) United States
(12) Patent Application Publication
(10) Pub. No.: US 2017/0133531 A1
(43) Pub. Date: May 11, 2017

(54) SOLAR CELL REAR SURFACE PROTECTIVE SHEET AND SOLAR CELL MODULE

(71) Applicant: FUJIFILM CORPORATION, Tokyo (JP)

(72) Inventor: Yu ISOBE, Fujinomiya-shi (JP)

(21) Appl. No.: 15/415,872

(22) Filed: Jan. 26, 2017

Related U.S. Application Data
(63) Continuation of application No. PCT/JP2015/066639, filed on Jun. 9, 2015.

(30) Foreign Application Priority Data
Aug. 29, 2014 (JP) 2014-176475

(51) Int. Cl. H01L 31/049; B29C 37/00; H01L 31/048; B29C 55/14

(52) U.S. Cl. CPC H01L 31/049; B29C 55/14; B29C 37/0025; H01L 31/0481; B29K 2067/00

(57) ABSTRACT

Provided are a solar cell rear surface protective sheet comprising: a base material film including a white polyester film and having a thickness of from 20 μm to 500 μm, a first resin layer having a modulus of tensile elasticity of 1.2 GPa or higher and 3.0 GPa or lower and a thickness of 1 μm or greater, and a second resin layer having a lower modulus of tensile elasticity than the first resin layer, which are laminated in this order.

### CROSS-REFERENCE TO RELATED APPLICATIONS

This application is a continuation application of International Application No. PCT/JP2015/066639, filed Jun. 9, 2015, the disclosure of which is incorporated herein by reference in its entirety. Further, this application claims priority from Japanese Patent Application No. 2014-176475, filed Aug. 29, 2014, the disclosure of which is incorporated herein by reference in its entirety.

### BACKGROUND OF THE INVENTION

1. Field of the Invention

The present invention relates to a solar cell rear surface protective sheet and a solar cell module.

2. Description of the Related Art

A solar cell module has a structure in which a solar cell, in which a solar cell element is sealed with a sealing material, is interposed between a front base material disposed on the front surface side on which, generally, sunlight is incident and a rear surface protective sheet (hereinafter, sometimes referred to as “solar cell back sheet” or simply referred to as “back sheet”) disposed on the side (rear surface side) opposite to the front surface side on which sunlight is incident. A sealing material such as an EVA (ethylene-vinyl acetate copolymer) resin is formed as a seal between the front base material and the solar cell and between the solar cell and the rear surface protective sheet. That is, in a case of using a polyester film in solar cell applications, adhesiveness between the polyester film and the sealing material is required.

Furthermore, an environment in which a solar cell module is generally used is an environment always exposed to outdoor weather such as the wind and the rain. Therefore, weather resistance of the solar cell rear surface protective sheet is also important.

Regarding the weather resistance of the solar cell rear surface protective sheet in such a wet heat environment, it is important to cause the solar cell rear surface protective sheet and the sealing material not to peel away from each other and it is important to cause, in a case where the solar cell rear surface protective sheet has a laminated structure, peeling between the layers in the solar cell rear surface protective sheet not to occur.

In addition, as functions imparted to the solar cell back sheet, for example, there may be cases where it is required to add a white pigment (white particles) such as titanium oxide to impart reflective performance. This is because power generation efficiency is increased by causing light that passes through the cell from sunlight incident on the front surface of the module to undergo diffuse reflection and return to the cell.

As a white film, a method of forming a white layer by applying a coating liquid including a white pigment or a white paint to a transparent polyester film, or using a white polyester film which is whitened by including a white pigment or forming fine cavities (voids) through foaming and stretching has been proposed (for example, JP2012-158754A).

### SUMMARY OF THE INVENTION

Since the white polyester film including the white pigment or voids has low moisture-heat resistance, when a general 180° peel test as an EVA adhesion evaluation method is conducted on a back sheet after a laminate of the back sheet and EVA which is a sealing material is exposed to wet heat, break in film easily occurs, and there may be cases where sufficient adhesion for practical use is not obtained. On the other hand, when break resistance is improved by increasing a heat setting temperature during production of the white polyester film, the hydrolysis resistance of the film decreases, resulting in insufficient weather resistance.

In addition, for example, JP2012-158754A describes that the adhesiveness to the sealing material is improved by providing a coating layer, and the coating layer has to have excellent long-term durability against moisture and high temperatures and has to have mechanical strength that safely withstands stress or strain generated during production of a film, winding, unwinding, and production of a solar module. However, specific materials and physical properties required of an adhesive layer for the sealing material are not described.

An object of the present invention is to provide a solar cell rear surface protective sheet which has a white polyester film and achieves both break resistance and adhesiveness of the film in a sealing material adhesion test after the film is adhered to a sealing material and is exposed to wet heat, and a solar cell module having long-term durability.

In order to achieve the object, the following inventions are provided.

<1> A solar cell rear surface protective sheet comprising: a base material film including a white polyester film, a first resin layer having a modulus of elasticity of 1.2 GPa or higher and 3.0 GPa or lower and a thickness of 1 μm or greater, and a second resin layer having a lower modulus of elasticity than the first resin layer, which are laminated in this order.

<2> The solar cell rear surface protective sheet described in <1>, in which the thickness of the first resin layer is 8 μm or smaller.

<3> The solar cell rear surface protective sheet described in <1> or <2>, in which the modulus of elasticity of the second resin layer is 150 MPa or lower.

<4> The solar cell rear surface protective sheet described in any one of <1> to <3>, in which the second resin layer includes an olefin-based resin.

<5> The solar cell rear surface protective sheet described in any one of <1> to <4>, in which a thickness of the second resin layer is 0.01 μm or greater and 1 μm or smaller.

<6> The solar cell rear surface protective sheet described in any one of <1> to <5>, in which the first resin layer includes at least one of an acrylic resin or an ester-based resin.

<7> The solar cell rear surface protective sheet described in any one of <1> to <6>, in which the white polyester film is a film produced through a heat setting process, and a heat setting temperature in the heat setting process is 180° C. or higher and 220° C. or lower.

<8> The solar cell rear surface protective sheet described in any one of <1> to <7>, in which the white polyester film includes inorganic particles as a whitening agent.

<9> The solar cell rear surface protective sheet described in <8>, in which a content of the inorganic particles included in the white polyester film is 0.1 mass % or more and 10 mass % or less.

<10> The solar cell rear surface protective sheet described in <8> or <9>, in which the inorganic particles included in the white polyester film are titanium oxide.

<11> A solar cell module comprising: an element structure portion which includes a solar cell element and a sealing material which seals the solar cell element; a transparent substrate which is positioned on a side of the element structure portion on which sunlight is incident; and the solar cell rear surface protective sheet according to any one of claims 1 to 10, which is positioned on a side opposite to the side of the element structure portion on which the substrate is positioned, and has the second resin layer adhered to the sealing material.

According to the present invention, a solar cell rear surface protective sheet which has a white polyester film and achieves both break resistance and adhesiveness of the film in a sealing material adhesion test after the film is adhered to a sealing material and is exposed to wet heat, and a solar cell module having long-term durability are provided.

### BRIEF DESCRIPTION OF THE DRAWINGS

FIG. 1 is a schematic view illustrating an example of a layer configuration of a solar cell rear surface protective sheet of the present invention.

FIG. 2 is a schematic view illustrating an example of a configuration of a solar cell module of the present invention.

### DESCRIPTION OF THE PREFERRED EMBODIMENTS

Hereinafter, a solar cell rear surface protective sheet according to an embodiment will be described in detail. In the following description, “to” which represents a numerical value range means a range including numerical values described as a lower limit and an upper limit.

<Solar Cell Rear Surface Protective Sheet>

The solar cell rear surface protective sheet of this disclosure has a structure in which a base material film including a white polyester film, a first resin layer having a modulus of elasticity of 1.2 GPa or higher and 3.0 GPa or lower and a thickness of 1 μm or greater, and a second resin layer having a lower modulus of elasticity than the first resin layer are laminated in this order.

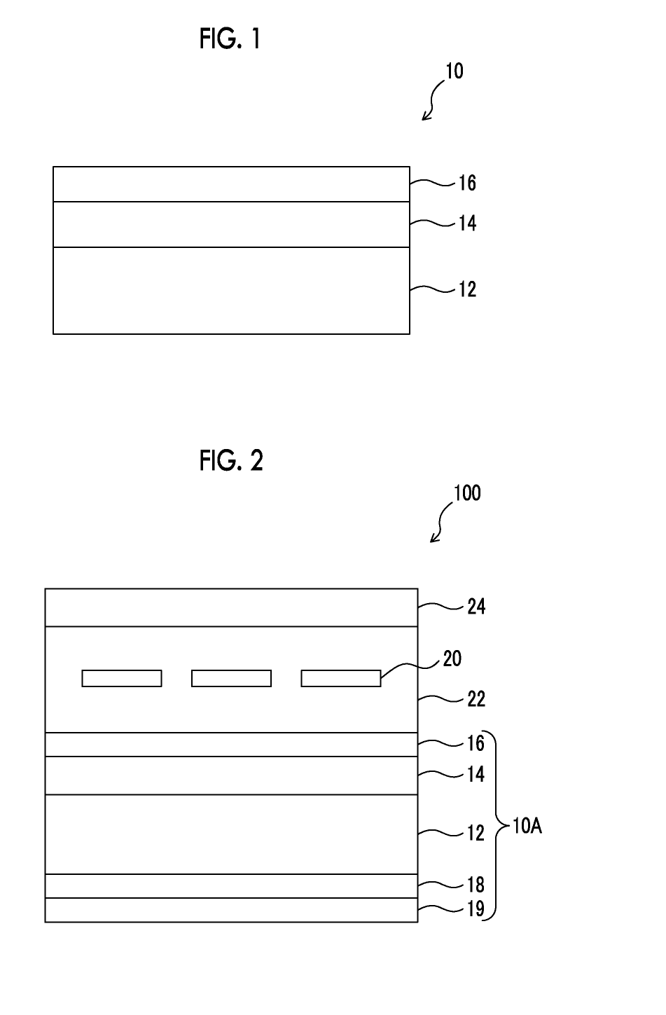

FIG. 1 schematically illustrates an example of a layer configuration of the solar cell rear surface protective sheet according to this disclosure. In a solar cell rear surface protective sheet 10 illustrated in FIG. 1, on one surface side of a base material film 12 (hereinafter, sometimes referred to as “base material film (A)”) including a white polyester film, a first resin layer 14 (hereinafter, sometimes referred to as “first resin layer (B)”), and a second resin layer 16 (hereinafter, sometimes referred to as “second resin layer (C)”) are laminated in this order.

Regarding the solar cell rear surface protective sheet of this disclosure, regardless of the use of the white polyester film, of which the breaking strength is easily lowered, as the base material film, even when an EVA adhesion test is conducted after the solar cell rear surface protective sheet of this disclosure is adhered to EVA and is exposed to wet heat, breaking of the white polyester film is suppressed, and excellent adhesiveness is provided. It is thought that the reason is that when a 180° peel test is conducted after the exposure to wet heat, the second resin layer is stretched at the interface between a sealing material and the second resin layer, thereby securing adhesion, and even though the second resin layer is broken, the first resin layer having a high modulus of elasticity functions as a protective layer, thereby preventing cracking and breaking of the white polyester film which forms the base material film. In addition, since the two resin layers are provided, breaking of the film is avoided. Therefore, there is no need to increase a heat setting temperature during production of the film, and thus both adhesiveness to the sealing material and the weather resistance of the film are achieved.

[Base Material Film (A)]

The solar cell rear surface protective sheet of this disclosure has the base material film (A) including the white polyester film.

The base material film (A) may be configured to have only the white polyester film, or may be configured to have an undercoat layer (so-called inline coating layer), which is formed through application and stretching during production of the white polyester film, in order to increase adhesiveness between the white polyester film and the first resin layer.

(White Polyester Film)

The white polyester film in this disclosure is configured to include at least polyester. The white polyester film is preferably whitened by including inorganic particles as a whitening agent from the viewpoint of ease of production, and may also be whitened by causing a polyester film to have a number of voids.

The kind of the polyester included in the white polyester film is not particularly limited, and well-known polyesters may be used.

Examples of the polyester include a linear saturated polyester synthesized from an aromatic dibasic acid or an ester-forming derivative thereof and a diol or an ester-forming derivative thereof. Specific examples of the linear saturated polyester include polyethylene terephthalate, polyethylene isophthalate, polybutylene terephthalate, poly(1,4-cyclohexylene dimethylene terephthalate), and polyethylene-2,6-naphthalate. Among these, in terms of the balance between mechanical properties and costs, polyethylene terephthalate, polyethylene-2,6-naphthalate, poly(1,4-cyclohexylene dimethylene terephthalate), and the like are particularly preferable.

The polyester may be a homopolymer or a copolymer. Furthermore, a small amount of another kind of resin such as polyimide may be blended in the polyester.

The kind of the polyester is not limited to the above-described polyester, and a well-known polyester may also be used. As the well-known polyester, a polyester may be synthesized by using a dicarboxylic acid component and a diol component. Otherwise, a commercially available polyester may also be used.

In a case where a polyester is synthesized, the polyester can be obtained by, for example, causing a (a) dicarboxylic acid component and a (b) diol component to undergo at least one of an esterification reaction or a transesterification reaction according to a well-known method.

Examples of the (a) dicarboxylic acid component include dicarboxylic acids or ester derivatives thereof including: aliphatic dicarboxylic acids such as malonic acid, succinic acid, glutaric acid, adipic acid, suberic acid, sebacic acid, dodecanedioic acid, dimer acid, eicosanedioic acid, pimelic acid, azelaic acid, methylmalonic acid, and ethylmalonic acid; alicyclic dicarboxylic acids such as adamantane dicarboxylic acid, norbornene dicarboxylic acid, cyclohexane dicarboxylic acid, and decalin dicarboxylic acid; and aromatic dicarboxylic acids such as terephthalic acid, isophthalic acid, phthalic acid, 1,4-naphthalene dicarboxylic acid, 1,5-naphthalene dicarboxylic acid, 2,6-naphthalene dicarboxylic acid, 1,8-naphthalene dicarboxylic acid, 4,4′-diphenyl dicarboxylic acid, 4,4′-diphenyl ether dicarboxylic acid, 5-sodium sulfoisophthalic acid, phenylindane dicarboxylic acid, anthracene dicarboxylic acid, phenanthrene dicarboxylic acid, and 9,9′-bis(4-carboxyphenyl) fluorensic acid.

Examples of the (b) diol component include diol compounds including: aliphatic diols such as ethylene glycol, 1,2-propanediol, 1,3-propanediol, 1,4-butanediol, 1,2-butanediol, and 1,3-butanediol; alicyclic diols such as cyclohexane dimethanol, spiroglycol, and isosorbide; and aromatic diols such as bisphenol A, 1,3-benzenedimethanol, 1,4-benzenedimethanol, and 9,9′-bis(4-hydroxyphenyl)fluorene.

As the (a) dicarboxylic acid component, at least one kind of the aromatic dicarboxylic acids is preferably used. More preferably, an aromatic dicarboxylic acid is included as a primary component in the dicarboxylic acid component. The “primary component” means that the proportion of the aromatic dicarboxylic acid in the dicarboxylic acid component is 80 mass % or more. A dicarboxylic acid component other than the aromatic dicarboxylic acid may also be included. As the dicarboxylic acid component, an ester derivative of an aromatic dicarboxylic acid or the like is used.

As the (b) diol component, at least one kind of the aliphatic diols is preferably used. As the aliphatic diol, ethylene glycol may be included, and ethylene glycol is preferably included as a primary component. The “primary component” means that the proportion of the ethylene glycol to the diol component is 80 mass % or more.

The amount of the aliphatic diol (for example, ethylene glycol) used is preferably in a range of 1.015 to 1.50 mol with respect to 1 mol of the aromatic dicarboxylic acid (for example, terephthalic acid) and, as necessary, an ester derivative thereof. The amount of the aliphatic diol used is more preferably in a range of 1.02 to 1.30 mol, and even more preferably in a range of 1.025 to 1.10 mol. When the amount of the aliphatic diol used is in a range of 1.015 mol or more, the esterification reaction favorably proceeds, and when the amount of the aliphatic diol used is in a range of 1.50 mol or less, for example, the generation of diethylene glycol as a byproduct due to the dimerization of ethylene glycol is suppressed, and characteristics such as melting point, glass transition temperature, crystallinity, heat resistance, hydrolysis resistance, and weather resistance can be favorably maintained.

In the esterification reaction or the transesterification reaction, a reaction catalyst which is hitherto well known may be used. As the reaction catalyst, alkali metal compounds, alkaline-earth metal compounds, zinc compounds, lead compounds, manganese compounds, cobalt compounds, aluminum compounds, antimony compounds, titanium compounds, and phosphorus compounds may be employed. Typically, in an arbitrary stage before the completion of a production method of the polyester, as a polymerization catalyst, an antimony compound, a germanium compound, a titanium compound, or the like is preferably added. As such a method, for example, when the germanium compound is exemplified, germanium compound powder is preferably added as it is.

For example, in the esterification reaction process, the aromatic dicarboxylic acid and the aliphatic diol are polymerized in the presence of a catalyst including a titanium compound. In this esterification reaction, as the titanium compound which serves as the catalyst, an organic chelate titanium complex having an organic acid as a ligand may be used, and the process may be provided with a procedure for adding at least the organic chelate titanium complex, a magnesium compound, and a pentavalent phosphoric acid ester with no aromatic ring as a substituent in this order.

Specifically, in the esterification reaction process, first, the aromatic dicarboxylic acid and the aliphatic diol are mixed with a catalyst including the organic chelate titanium complex, which is a titanium compound, before the addition of a magnesium compound and a phosphorus compound. The titanium compound such as the organic chelate titanium complex has a strong catalytic activity for the esterification reaction and is thus capable of causing the esterification reaction to favorably proceed. At this time, the titanium compound may be added while of the aromatic dicarboxylic acid component and the aliphatic diol component are mixed together, or the aliphatic diol component (or the aromatic dicarboxylic acid component) may be mixed after the aromatic dicarboxylic acid component (or the aliphatic diol component) and the titanium compound are mixed together. Otherwise, the aromatic dicarboxylic acid component, the aliphatic diol component, and the titanium compound may be mixed together at the same time. Mixing is not particularly limited to this method, and may be carried out by a well-known method.

When the polyester is synthesized, the following compounds are preferably added.

As a pentavalent phosphorus compound, at least one pentavalent phosphoric acid ester with no aromatic ring as a substituent is used. For example, a phosphoric acid ester [(OR)₃—P═O; R is an alkyl group having 1 or 2 carbon atoms] having a lower alkyl group having 2 or less carbon atoms as a substituent may be employed. Specifically, trimethyl phosphate, triethyl phosphate, and the like are particularly preferable.

The amount of the phosphorus compound added is preferably in a range of 50 ppm to 90 ppm in terms of a P element-equivalent value. The amount of the phosphorus compound is more preferably 60 ppm to 80 ppm, and even more preferably 60 ppm to 75 ppm.

By including a magnesium compound in the polyester, the electrostatic application property of the polyester improves.

Examples of the magnesium compound include magnesium salts such as magnesium oxide, magnesium hydroxide, magnesium alkoxide, magnesium acetate, and magnesium carbonate. Among these, from the viewpoint of solubility in ethylene glycol, magnesium acetate is the most preferable.

In order to impart a high electrostatic application property, the amount of the magnesium compound added is preferably 50 ppm or more in terms of a Mg element-equivalent value, and is more preferably in a range of 50 ppm to 100 ppm. The amount of the magnesium compound added is preferably in a range of 60 ppm to 90 ppm and even more preferably in a range of 70 ppm to 80 ppm in terms of imparting the electrostatic application property.

In the esterification reaction process, it is particularly preferable that the titanium compound as a catalyst component and the magnesium compound and the phosphorus compound as additives are added to be subjected to melt polymerization so that a value Z calculated from the following expression (i) satisfies the following relational expression (ii). Here, the P content refers to the amount of phosphorus derived from all phosphorus compounds including the pentavalent phosphoric acid ester with no aromatic ring, and the Ti content refers to the amount of titanium derived from all Ti compounds including the organic chelate titanium complex. As described above, by selecting a combination of the magnesium compound and the phosphorus compound in a catalytic system including a titanium compound and controlling the addition timings and addition proportions thereof, a polyester with a slight yellow tint tone can be obtained while appropriately maintaining the catalytic activity of the titanium compound at a high level. Accordingly, heat resistance at a degree at which yellow coloration is less likely to occur even when the polyester is exposed to a high temperature during a polymerization reaction or during subsequent film production (during melting) can be provided.

Z=5×(P content[ppm]/atomic weight of P)−2×(Mg content[ppm]/atomic weight of Mg)−4×(Ti content[ppm]/atomic weight of Ti) (i)

0≦Z≦5.0 (ii)

Since the phosphorus compound not only acts on titanium but also interacts with the magnesium compound, this serves as an index quantitatively representing the balance between the three.

Expression (i) represents the amount of phosphorus capable of acting on titanium by subtracting the amount of phosphorus that acts on magnesium from the total amount of phosphorus that can react. It can be said that, in a case where the value Z is a positive value, the amount of phosphorus that inhibits titanium is in an excessive state, and, conversely, in a case where the value Z is a negative value, the amount of phosphorus necessary to inhibit titanium is in an insufficient state. In the reaction, since a Ti atom, a Mg atom, and a P atom do not have equal valences, weighting is carried out by multiplying the mole numbers of the respective atoms in the expression by the valency numbers.

Specific synthesis or the like is unnecessary for the synthesis of the polyester, and by using the titanium compound which is inexpensive and can be easily procured, and the phosphorus compound and the magnesium compound which are described above, a polyester having a reaction activity required for the reaction and excellent tone and coloration resistance against heat can be obtained.

In Expression (ii), from the viewpoint of further improving the tone and coloration resistance against heat in a state of maintaining the polymerization reactivity, it is preferable to satisfy 1.0≦Z≦4.0, and it is more preferable to satisfy 1.5≦Z≦3.0.

As a suitable aspect of the esterification reaction process, 1 ppm to 30 ppm of a chelate titanium complex having citric acid or citrate as a ligand may be added to the aromatic dicarboxylic acid and the aliphatic diol before the completion of the esterification reaction. Thereafter, it is preferable to add 60 ppm to 90 ppm (more preferably 70 ppm to 80 ppm) of a weakly acidic magnesium salt in the presence of the chelate titanium complex and after the above-described addition, further add 60 ppm to 80 ppm (more preferably 65 ppm to 75 ppm) of the pentavalent phosphoric acid ester with no aromatic ring as a substituent.

The esterification reaction process may be carried out while removing water or alcohols generated due to the reaction to be discharged to the outside of the system using a multi-stage apparatus including at least two reactors connected in series, under a condition in which ethylene glycol is refluxed.

The esterification reaction process may be carried out in a single stage or may be carried out in multiple separated stages.

In a case where the esterification reaction process is carried out in a single stage, the temperature of the esterification reaction is preferably 230° C. to 260° C. and more preferably 240° C. to 250° C.

In a case where the esterification reaction process is carried out in multiple separated stages, the temperature of the esterification reaction in a first reactor is preferably 230° C. to 260° C. and more preferably 240° C. to 250° C., and the pressure is preferably 1.0 kg/cm² to 5.0 kg/cm², and more preferably 2.0 kg/cm² to 3.0 kg/cm². The temperature of the esterification reaction in a second reactor is preferably 230° C. to 260° C., and more preferably 245° C. to 255° C., and the pressure is 0.5 kg/cm² to 5.0 kg/cm², and more preferably 1.0 kg/cm² to 3.0 kg/cm². Furthermore, in a case where the esterification reaction process is carried out in three or more separated stages, conditions for the esterification reaction in an intermediate stage are set to conditions between those in a first reactor and those in a final reactor.

Meanwhile, a polycondensation reaction of an esterification reaction product generated in the esterification reaction is caused so as to generate a polycondensate. The polycondensation reaction may be caused in a single stage or may be caused in multiple separated stages.

The esterification reaction product such as an oligomer generated in the esterification reaction is subsequently subjected to a polycondensation reaction. This polycondensation reaction can be suitably caused by supplying the esterification reaction product to a multi-stage polycondensation reactor.

For example, as for conditions of the polycondensation reaction in a case where the polycondensation reaction is caused in reactors in three stages, in the first reactor, the reaction temperature is 255° C. to 280° C. and more preferably 265° C. to 275° C. and the pressure is 100 torr to 10 torr (13.3×10⁻³ MPa to 1.3×10⁻³ MPa) and more preferably 50 torr to 20 torr (6.67×10⁻³ MPa to 2.67×10⁻³ MPa), in the second reactor, the reaction temperature is 265° C. to 285° C. and more preferably 270° C. to 280° C. and the pressure is 20 torr to 1 torr (2.67×10⁻³ MPa to 1.33×10⁻⁴ MPa) and more preferably 10 torr to 3 torr (1.33×10⁻³ MPa to 4.0×10⁻⁴ MPa), and in the third reactor in the final reactor, the reaction temperature is 270° C. to 290° C. and more preferably 275° C. to 285° C. and the pressure is 10 torr to 0.1 torr (1.33×10⁻³ MPa to 1.33×10⁻⁵ MPa) and more preferably 5 torr to 0.5 torr (6.67×10⁻⁴ MPa to 6.67×10⁻⁵ MPa).

The polyester synthesized as described above may further include additives such as a light stabilizer, an antioxidant, an ultraviolet absorber, a flame retardant, a lubricant (fine particles), a nucleating agent (crystallization agent), and a crystallization inhibitor.

During the synthesis of the polyester, after the polyester is polymerized by the esterification reaction, it is preferable to carry out solid-phase polymerization. By causing the polyester to undergo solid-phase polymerization, the moisture content of the polyester, the degree of crystallization, the acid value of the polyester, that is, the concentration of a terminal carboxyl group of the polyester, and the intrinsic viscosity can be controlled.

Particularly, it is preferable to carry out the solid-phase polymerization by setting the concentration of ethylene glycol (EG) gas at the initiation of the solid-phase polymerization to be higher than the concentration of the EG gas at the end of the solid-phase polymerization, preferably in a range of 200 ppm to 1000 ppm, more preferably 250 ppm to 800 ppm, and even more preferably in a range of 300 ppm to 700 ppm. At this time, the concentration (Acid Value (AV)) of terminal COOH can be controlled by adding the average EG gas concentration (the average of the gas concentrations at the initiation and at the end of the solid-phase polymerization). That is, by adding EG to react with the terminal COOH, the AV can be reduced. The concentration of EG is preferably 100 ppm to 500 ppm, more preferably 150 ppm to 450 ppm, and even more preferably 200 ppm to 400 ppm.

In addition, the temperature of the solid-phase polymerization is preferably 180° C. to 230° C., more preferably 190° C. to 215° C., and even more preferably 195° C. to 209° C.

In addition, the solid-phase polymerization time is preferably 10 hours to 40 hours, more preferably 14 hours to 35 hours, and even more preferably 18 hours to 30 hours.

Here, the polyester preferably has strong hydrolysis resistance. Therefore, the content of the carboxyl group in the polyester is preferably 50 eq/t (here, ‘t’ represents ton, and ton means 1000 kg) or less, more preferably 35 eq/t or less, and even more preferably 20 eq/t or less. When the content of the carboxyl group is 50 eq/t or less, hydrolysis resistance can be maintained and a decrease in strength can be suppressed during exposure to moisture and heat for a period of time. The lower limit of the content of the carboxyl group is preferably 2 eq/t, and more preferably 3 eq/t in terms of maintaining the adhesiveness to a layer formed on the surface of the polyester film (for example, the resin layers).

The content of the carboxyl group in the polyester can be adjusted by the kind of a polymerization catalyst, film production conditions (film production temperature and time), solid-phase polymerization, and additives (a terminal sealing agent and the like).

—Carbodiimide Compound and Ketenimine Compound—

The polyester film of which the raw material resin is polyester may include at least one of a carbodiimide compound or a ketenimine compound. The carbodiimide compound and the ketenimine compound may be used singly or in a combination of the two. Accordingly, deterioration of the polyester in a wet heat environment is prevented, which is effective in maintaining strong insulating properties even in the wet heat environment.

The carbodiimide compound or the ketenimine compound is included preferably in a proportion of 0.1 mass % to 10 mass % in the polyester, more preferably in a proportion of 0.1 mass % to 4 mass %, and even more preferably in a proportion of 0.1 mass % to 2 mass %. When the content of the carbodiimide compound or the ketenimine compound is set in the above-described range, the adhesiveness between a base material and an adjacent layer can be enhanced. In addition, the heat resistance of the base material can be enhanced.

In a case where the carbodiimide compound and the ketenimine compound are used in combination, it is preferable that the sum of the contents of the two compounds is in the above-described range.

As the carbodiimide compound, a compound (including a polycarbodiimide compound) having one or more carbodiimide groups in a molecule may be employed. Specifically, examples of a monocarbodiimide compound include dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphthylcarbodiimide, and N,N′-di-2,6-diisopropylphenylcarbodiimide.

Examples of the polycarbodiimide compound include polycarbodiimide compounds in which the lower limit of the degree of polymerization is typically 2 or higher and preferably 4 or higher, and the upper limit of the degree of polymerization is typically 40 or lower and preferably 30 or lower. Polycarbodiimide compounds produced using the methods described in the specification of U.S. Pat. No. 2,941,956A, JP1972-33279B (JP-S47-33279B), J. Org. Chem. Vol. 28, pp. 2069 to 2075 (1963), Chemical Review 1981, Vol. 81, Issue 4, pp. 619 to 621, and the like may be employed.

Examples of an organic diisocyanate, which is a raw material for producing the polycarbodiimide compound, include aromatic diisocyanates, aliphatic diisocyanates, alicyclic diisocyanates, and mixtures thereof. Specific examples thereof include 1,5-naphthalene diisocyanate, 4,4′-diphenylmethane diisocyanate, 4,4′-diphenyldimethylmethane diisocyanate, 1,3-phenylene diisocyanate, 1,4-phenylene diisocyanate, 2,4-tolylene diisocyanate, 2,6-tolylene diisocyanate, a mixture of 2,4-tolylene diisocyanate and 2,6-tolylene diisocyanate, hexamethylene diisocyanate, cyclohexane-1,4-diisocyanate, xylylene diisocyanate, isophorone diisocyanate, 4,4′-dicyclohexylmethane diisocyanate, methylcyclohexane diisocyanate, tetramethylxylylene diisocyanate, 2,6-diisopropylphenyl isocyanate, and 1,3,5-triisopropylbenzene-2,4-diisocyanate.

A specific polycarbodiimide compound that can be industrially procured is exemplified by CARBODILITE (registered trademark) HMV-8CA (manufactured by Nisshinbo Chemical Inc.), CARBODILITE (registered trademark) LA-1 (manufactured by Nisshinbo Chemical Inc.), STABAXOL (registered trademark) P (manufactured by Rhein Chemie Corporation), STABAXOL (registered trademark) P100 (manufactured by Rhein Chemie Corporation), STABAXOL (registered trade mark) P400 (Rhein Chemie Corporation), and STABILIZER 9000 (manufactured by RASCHIG GmbH).

The carbodiimide compound may be used singly, but a mixture of a plurality of the compounds may also be used.

As the ketenimine compound, a ketenimine compound represented by General Formula (K-A) shown below is preferably used.

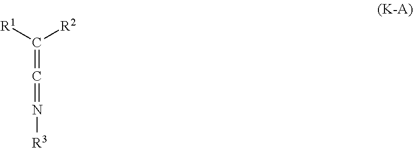

In General Formula (K-A), R¹ and R² each independently represent an alkyl group, an aryl group, an alkoxy group, an alkoxycarbonyl group, an aminocarbonyl group, an aryloxy group, an acyl group, or an aryloxycarbonyl group, and R³ represents an alkyl group or an aryl group.

Here, the molecular weight of a portion excluding the nitrogen atom and the substituent R³ bonded to the nitrogen atom in the ketenimine compound is preferably 320 or more. That is, in General Formula (K-A), the molecular weight of a R¹—C(═C)—R² group is preferably 320 or more. The molecular weight of the portion excluding the nitrogen atom and the substituent R³ bonded to the nitrogen atom in the ketenimine compound is preferably 320 or higher, more preferably 500 to 1500, and even more preferably 600 to 1000. As described above, by causing the molecular weight of the portion excluding the nitrogen atom and the substituent R³ bonded to the nitrogen atom to be in the above-described range, the adhesiveness between the base material film (A) and a layer that is in contact therewith can be increased. This is because, when the portion excluding the nitrogen atom and the substituent R³ bonded to the nitrogen atom has a certain range of molecular weight, the polyester terminal which is bulky to a certain extent diffuses into the layer that is in contact with the base material film (A), and an anchorage effect is exhibited.

Here, the molecular weight of the portion excluding the nitrogen atom and the substituent R³ bonded to the nitrogen atom in the ketenimine compound is preferably 320 or higher. The molecular weight of the portion excluding the nitrogen atom and the substituent bonded to the nitrogen atom in the ketenimine compound may be 320 or higher, preferably 400 or higher, and more preferably 500 or higher. In addition, the molar molecular weight of the ketenimine compound with respect to the number of ketenimine groups in a molecule (the molar molecular weight/the number of ketenimine groups) is preferably 1000 or less, more preferably 500 or less, and even more preferably 400 or less. By causing the molecular weight of the portion excluding the nitrogen atom and the substituent R³ bonded to the nitrogen atom in the ketenimine compound and the molar molecular weight of the ketenimine compound with respect to the number of ketenimine groups to be in the above-described ranges, the sublimation of the ketenimine compound itself is suppressed, the sublimation of the ketene compound generated when the terminal carboxyl group of the polyester is sealed is suppressed, and furthermore, the terminal carboxyl group of the polyester can be sealed with a small amount of the ketenimine compound added.

The ketenimine compound having at least one ketenimine group can be synthesized with reference to the method described in, for example, J. Am. Chem. Soc., 1953, 75(3), pp. 657 to 660.

—Whitening—

In this disclosure, it is preferable that the white polyester film is whitened by including inorganic particles as a whitening agent, in addition to the polyester.

As the base material film (A) exhibits white color, light reflectance (whiteness) can be improved, and the power generation efficiency of the solar cell can be increased.

The average particle diameter of the inorganic particles as the whitening agent is preferably 0.1 to 10 μm, more preferably 0.1 to 5 μm, and even more preferably 0.15 to 1 μm. When the average particle diameter of the particles is 0.1 to 10 μm, the whiteness of the film can be caused to be 50 or higher.

The content of the inorganic particles as the whitening agent in the white polyester film is preferably 0.1 mass % to 10 mass % and more preferably 1 mass % to 8 mass % with respect to the white polyester film. When the content of the inorganic particles is more than 0.1 mass %, superiority in reflectance can be obtained compared to a case where a transparent polyester film is used. When the content thereof is 10 mass % or less, not only can an increase in costs be suppressed, but also a reduction in the strength of the base material film (A) can be suppressed.

The average particle diameter and content of the inorganic particles represent an average value of each layer in a case where the white polyester film has a multilayer structure. That is, (the particle diameter or content of inorganic particles in each layer)×(the thickness of each layer/the thickness of all layers) is calculate for each layer, and the sum thereof is obtained.

The average particle diameter of the inorganic particles included in the white polyester film in this disclosure is obtained by an electron microscopic method, specifically, according to the following method.

Particles are observed with a scanning electron microscope, and photographs taken by appropriately changing the magnification according to the size of the particles are enlarged and copied. Next, for at least 200 particles randomly selected, the outer circumference of each of the particles is traced. The equivalent circle diameters of the particles are measured from the traced images by an image analyzer, and the average value thereof is determined as the average particle diameter.

As the inorganic particles as the whitening agent, inorganic particles exhibiting white color (hereinafter, sometimes referred to as “white particles”) such as wet and dry silica, colloidal silica, calcium carbonate, aluminum silicate, calcium phosphate, alumina, magnesium carbonate, zinc carbonate, titanium oxide, zinc oxide (zinc white), antimony oxide, cerium oxide, zirconium oxide, tin oxide, lanthanum oxide, magnesium oxide, barium carbonate, zinc carbonate, a basic lead carbonate (white lead), barium sulfate, calcium sulfate, lead sulfate, zinc sulfide, mica, titanated mica, talc, clay, kaolin, lithium fluoride, and calcium fluoride may be used. From the viewpoint of costs and availability, titanium oxide and barium sulfate are preferable. The titanium oxide may be in the form of either anatase or rutile type. In addition, an inorganic treatment based on alumina, silica, or the like may be carried out on the surfaces of the particles, or an organic treatment based on silicone, alcohol, or the like may also be carried out thereon.

Among these, titanium oxide is preferable, and as the titanium oxide is used, light reflectivity and excellent durability even in an environment irradiated with light can be exhibited. Specifically, in a case where UV (ultraviolet rays) irradiation is carried out at 63 □, 50% Rh, and an irradiation intensity of 100 mW/cm² for 100 hours, the elongation at break retention ratio is preferably 35% or higher, and more preferably 40% or higher. As described above, when photolysis or deterioration in the white polyester film is suppressed even when the white polyester film is irradiated with light, the white polyester film is suitable for the rear surface protective sheet of a solar cell used outdoors.

As the titanium oxide, rutile and anatase types are present. However, the white polyester film in this disclosure is preferably whitened by adding titanium oxide particles including the rutile type as a primary body. While the anatase type has an extremely high ultraviolet spectral reflectance, the rutile type has a property of having a high ultraviolet absorbance (low spectral reflectance). Focused on the difference in spectral characteristics between the crystalline forms of titanium oxide, the light resistance of the solar cell rear surface protective sheet can be improved by using the ultraviolent absorption performance of the rutile type. Accordingly, excellent film durability is achieved in an environment irradiated with light even when another ultraviolet absorber is not substantially added. Therefore, contamination or a reduction in adhesiveness due to bleeding out of an ultraviolet absorber is less likely to occur.

As described above, it is preferable that the titanium oxide particles in this disclosure include the rutile type as the primary body. The “primary body” mentioned here means that the amount of rutile type titanium oxide in the total titanium oxide particles exceeds 50 mass %.

In addition, the amount of anatase type titanium oxide in the total titanium oxide particles is preferably 10 mass % or less, more preferably 5 mass % or less, and particularly preferably 0 mass %. When the content of anatase type titanium oxide exceeds the upper limit, the amount of rutile type titanium oxide included in the total titanium oxide particles is small, and there may be cases where ultraviolet absorption performance becomes insufficient. In addition, since anatase type titanium oxide has a strong photocatalytic action, this action tends to cause a reduction in light resistance. Rutile type titanium oxide and anatase type titanium oxide can be distinguished from each other through X-ray structural diffraction or spectral absorption characteristics.

Regarding the rutile type titanium oxide particles in this disclosure, an inorganic treatment based on alumina, silica, or the like may be carried out on the surfaces of the particles, or an organic treatment based on silicone, alcohol, or the like may also be carried out thereon. Rutile type titanium oxide may be subjected to particle diameter adjustment and coarse particle removal using a refining process before being mixed in the polyester. As industrial means of the refining process, for example, a jet mill or a ball mill can be applied as grinding means, and for example, dry or wet centrifugation can be applied as classifying means.

In this disclosure, organic particles may also be used as the whitening agent. As the organic particles, those that withstand heat during production of a polyester film are preferable, and for example, those made of cross-linked resins are used. Specifically, polystyrene cross-linked with divinylbenzene or the like is used. The size and amount of the particles added are the same as in the case of the inorganic particles.

Both the inorganic particles and the organic particles may also be used in combination. Accordingly, the light reflectance can be improved, and the power generation efficiency of a solar cell can be increased.

When particles are added as the whitening agent in the white polyester film, various well-known methods may be used. As representative methods, the following methods may be employed.

(A) A method of adding particles before the end of a transesterification reaction or an esterification reaction during synthesis of polyethylene terephthalate, or adding particles before the start of a polycondensation reaction.

(B) A method of adding particles to polyethylene terephthalate and melting and kneading the resultant.

(C) A method of producing master pellets (or also referred to as masterbatch (MB)) to which a large amount of particles are added in the (A) or (B) method, and kneading these with polyethylene terephthalate that does not include particles such that a predetermined amount of particles are included therein.

(D) A method of using the master pellets of (C) as they are.

Among these, the masterbatch method (MB method: (C)) in which a polyester resin and particles are mixed in an extruder in advance is preferable. Otherwise, a method of injecting a polyester resin which is not dried in advance and particles, into an extruder and producing MB while degassing moisture, air, and the like may also be employed. More preferably, when MB is produced using a polyester resin which is slightly dried in advance, an increase in the acid value of the polyester is suppressed. In this case, a method of carrying out extrusion while degassing is carried out, a method of extruding a polyester resin, which is sufficiently dried, without degassing, or the like may be employed.

For example, in a case of producing MB, it is preferable to dry the polyester resin, which is to be injected, in advance to reduce the moisture content thereof. As for drying conditions, drying is carried out at preferably 100° C. to 200° C. and more preferably 120° C. to 180° C., for 1 hour or longer, more preferably 3 hours or longer, and even more preferably 6 hours or longer. Accordingly, drying is sufficiently carried out so that the moisture content of the polyester resin reaches preferably 50 ppm or lower, and more preferably 30 ppm or lower. A preliminary mixing method is not particularly limited, and a batch mixing method may be employed. Otherwise, mixing may be carried out by a kneading extruder with a single screw or two or more screws. In a case of producing MB while degassing is carried out, a method of melting a polyester resin at a temperature of 250° C. to 300° C., and preferably 270° C. to 280° C., providing one, or preferably two or more degassing ports in a preliminary kneader, carrying out continuous suction degassing at 0.05 MPa or higher, and more preferably 0.1 MPa or higher, and maintaining the reduced pressure in a mixer, and the like are preferably employed.

The white polyester film according to this disclosure may exhibit white color by including a large number of fine cavities (voids) therein. By the voids, a high degree of whiteness can be suitably obtained. The apparent specific gravity of the white polyester film in this case is 0.7 or higher and 1.3 or lower, preferably 0.9 or higher and 1.3 or lower, and more preferably 1.05 or higher and 1.2 or lower. When the apparent specific gravity thereof is 0.7 or higher, the base material film (A) is provided with strength, and processing is facilitated during the production of a solar cell module. An apparent specific gravity of 1.3 or lower contributes to a reduction in the weight of the esolar cell module, since the weight of the white polyester film is low.

The fine cavities (voids) can be derived from a thermoplastic resin immiscible with the particles and/or the polyester, which will be described later. The cavities derived from the thermoplastic resin immiscible with the particles or polyester mean the presence of cavities in the periphery of the thermoplastic resin, and can be checked, for example, by cross-section photographs of the base material film (A) taken by an electronic microscope.

As the resin added to the polyester film to form cavities, a resin immiscible with polyester is preferable. Accordingly, light is scattered and light reflectance can be increased. As a preferable immiscible resin, polyolefin resins such as polyethylene, polypropylene, polybutene, and polymethylpentene, polystyrene resins, polyacrylate resins, polycarbonate resins, polyacrylonitrile resins, polyphenylene sulfide resins, polysulfone-based resins, cellulose-based resins, fluorine-based resins, and the like may be employed. Such an immiscible resin may be a homopolymer or a copolymer, or two or more kinds of immiscible resin may be used in combination. Among these, a polyolefin resin such as polypropylene or polymethylpentene with low surface tension or a polystyrene-based resin is preferable, and polymethylpentene is the most preferable. Polymethylpentene has a relatively great difference in surface tension from polyester and has a high melting point. Therefore, polymethylpentene has low affinity with polyester during the production process of polyester, easily forms voids (cavities), and is thus particularly preferable as the immiscible resin.

In a case of including the immiscible resin, the amount thereof is preferably 30 mass % or less with respect to the entire white polyester film, more preferably 1 to 20 mass %, and even more preferably in a range of 2 to 15 mass %. In a case where the content of the immiscible resin is in the above-described range, a high reflectance is achieved, the apparent density of the entire base material film (A) is not excessively reduced, breaking of the film during stretching is less likely to occur, and a reduction in productivity can be prevented.

In a case where particles for forming voids are added, the average particle diameter of the particles is preferably 0.1 to 10 μm, more preferably 0.1 to 5 μm, and even more preferably 0.15 to 1 μm. In this range, a high reflectance (whiteness) is obtained, and a reduction in mechanical strength is suppressed. The content of the particles is preferably 50 mass % or less with respect to the total mass of the white polyester film, more preferably 1 to 10 mass %, and even more preferably 2 to 5 mass %. In this range, a high reflectance (whiteness) is achieved, and a reduction in mechanical strength due to the voids is suppressed. As preferable particles, those having low affinity with polyester may be employed, and specifically, barium sulfate and the like may be employed.

The white polyester film according to this disclosure may have a single layer or a laminated configuration consisting of multiple layers such as two or more layers. As the laminated configuration, a combination of layers with high whiteness (layers with a large number of white particles or voids) and layers with low whiteness (layers with a small number of white particles or voids) is preferable. The layers with a large number of white particles or voids can increase light reflection efficiency. However, a reduction (embrittlement) in mechanical strength due to the white particles of voids is likely to occur. In order to compensate for this, a combination with the layers with low whiteness is preferable. Therefore, the layer with high whiteness is preferably used as an outer layer, and may be used on one surface or both surfaces of the white polyester film. In addition, when a high white layer using titanium oxide as white particles is used as the outer layer, the high white layer has a UV absorbing ability and has an effect of improving light resistance.

Even in a case of a white polyester film in which layers with high whiteness and layers with low whiteness are laminated, the content of the inorganic particles as the whitening agent in the entire white polyester film is preferably 0.1 mass % to 10 mass % with respect to the white polyester film. However, in a case of adding particles, the layers with high whiteness have an amount of particles of preferably 5 mass % or more and 50 mass % or less, and more preferably 6 mass % or more and 20 mass % or less. In a case of forming cavities, the apparent specific gravity of the layers with high whiteness is preferably 0.7 or higher and 1.2 or lower, and more preferably 0.8 or higher and 1.1 or lower.

On the other hand, in the case of adding particles, the layers with low whiteness preferably has an amount of particles of preferably less than 5 mass % and equal to or more than 0 mass %, and more preferably 4 mass % or less and 1 mass % or more. In a case of forming cavities, the layers with low whiteness preferably have an apparent specific gravity of 0.9 or higher and 1.4 or lower and have a higher density than that of the high white layer, and more preferably have an apparent specific gravity of 1.0 or higher and 1.3 or lower and have a higher density than that of the high white layer. A low white layer may not include particles of cavities.

As a preferable layer configuration, high white layer/low white layer, high white layer/low white layer/high white layer, high white layer/low white layer/high white layer/low white layer, high white layer/low white layer/high white layer/low white layer/high white layer, and the like may be employed.

The ratio between the thicknesses of the layers is not particularly limited, and the thickness of each layer is preferably 1% or greater and 99% or smaller of the thickness of all the layers, and more preferably 2% or greater and 95% or smaller. When the thickness is greater than the upper limit or smaller than the lower limit of this range, it is difficult to obtain an increase in the reflection efficiency and the effect of imparting light (UV) resistance.

As a lamination method in a case where the white polyester film according to this disclosure has the laminated structure, a so-called coextrusion method in which two or three or more melting extruders are used is preferably used.

In order to increase whiteness in this disclosure, it is preferable to use a fluorescent whitening agent such as thiophenediyl. The amount of the fluorescent whitening agent added is preferably 0.01 mass % or more and 1 mass % or less, more preferably 0.05 mass % or more and 0.5 mass % or less, and even more preferably 0.1 mass % or more and 0.3 mass % or less. In this range, an effect of improving light reflectance is easily obtained, and yellowing cause by pyrolysis due to extrusion is suppressed, and a reduction in reflectance is suppressed. As the fluorescent whitening agent, for example, OB-1 manufactured by Eastman Kodak Company may be used.

After the white polyester film used as the base material film (A) in this disclosure is irradiated with ultraviolet rays at an illuminance of 100 mW/cm², a temperature of 60° C., and a relative humidity of 50% RH for an irradiation time of 48 hours, a yellow tone change amount (Δb) value) is preferably lower than 5. The Δb value is more preferably lower than 4, and even more preferably lower than 3. Accordingly, even when the film is irradiated with sunlight for a long period of time, a change in color can be reduced. Therefore, the film is useful. In a case of the laminated type, this effect is significantly exhibited particularly in a case where the back sheet side of the solar cell module is irradiated.

The thickness of the white polyester film used as the base material film (A) in this disclosure is not particularly limited as long as the thickness is in a range in which a film can be produced, and is typically 20 μm to 500 μm, and preferably in a range of 30 μm to 300 μm.

(Undercoat Layer)

The base material film (A) may have, in addition to the white polyester film, an undercoat layer (inline coating layer) formed by a so-called inline coating method. That is, the undercoat layer is formed by applying an undercoat layer forming composition onto one surface of an un-stretched white polyester film or a white polyester film stretched in a first direction, and stretching the resultant in a second direction perpendicular to the first direction.

—Inline Coating Method—

The undercoat layer of this disclosure is formed by a so-called inline coating method, which is distinguished from an offline coating method in which after a film is wound partway and application is separately carried out.

When the undercoat layer is formed by the inline coating method, the adhesiveness between the white polyester film and the undercoat layer constituting the base material film (A) is improved, and this is advantageous in terms of productivity.

The thickness of the undercoat layer is preferably 0.01 μm to 1 μm. The thickness of the undercoat layer is preferably 0.01 μm or greater, more preferably 0.03 μm or greater, and even more preferably 0.05 μm or greater. In addition, the thickness of the undercoat layer is preferably 1 μm or smaller, more preferably 0.8 μm or smaller, and even more preferably 0.7 μm or smaller.

—Undercoat Layer Forming Composition—

For example, the undercoat layer of this disclosure is formed by applying, as the undercoat layer forming composition, a solution in which a resin component described below is dissolved in an appropriate solvent, or a dispersion in which the resin component is dispersed in a dispersion medium, onto the polyester film stretched in the first direction, and stretching the resultant in the second direction perpendicular to the first direction along the film surface. In addition to the resin component and the solvent or the dispersion medium, other additives may be included in the undercoat layer forming composition as necessary. In consideration of environmental load, an aqueous dispersion dispersed in water is preferably used in the undercoat layer forming composition.

In this disclosure, a method for obtaining the aqueous dispersion is not particularly limited. For example, as exemplified in JP2003-119328A, a method of heating and stirring the components described above, that is, the resin component, water, and an organic solvent as necessary, preferably in a sealable container may be employed, and this method is the most preferable. In this method, the resin component can be favorably formed in an aqueous dispersion even though a non-volatile aqueous aid is not actually added thereto.

The concentration of solid contents of the resin in the aqueous dispersion is not particularly limited. However, in terms of ease of coating and ease of adjustment of the thickness of the undercoat layer, the concentration of solid contents of the resin with respect to the total mass of the aqueous dispersion is preferably 1 mass % to 60 mass %, more preferably 2 mass % to 50 mass %, and even more preferably 5 mass % to 30 mass %.

—Resin Component—

The resin component included in the undercoat layer in this disclosure is not particularly limited as long as a layer can be formed by the inline coating method in the production process of the white polyester film. Examples of the resin component included in the undercoat layer include an acrylic resin, a polyester resin, a polyolefin resin, and silicone. In addition, a composite resin may be used, for example, an acrylic resin/silicone composite resin is also preferable.

˜Acrylic Resin˜

As the acrylic resin, for example, a polymer including polymethyl methacrylate, polyethyl acrylate, or polybutyl methacrylate is preferable.

As the acrylic resin, a commercially available product which is released may be used. Examples thereof include AS-563A (manufactured by Daicel FineChem Ltd.), and JURYMER (registered trademark) ET-410 and SEK-301 (both manufactured by Toagosei Co., Ltd.).

As the acrylic resin, from the viewpoint of modulus of elasticity in a case of being used in the undercoat layer, an acrylic resin including polymethyl methacrylate or polyethyl acrylate is more preferable, and an acrylic resin including a styrene skeleton is even more preferable.

As a composite resin of an acrylic resin and silicone, CERANATE (registered trademark) WSA1060 and WSA1070 (both manufactured by DIC Corporation), and H7620, H7630, and H7650 (all manufactured by Asahi Kasei Corporation) may be employed.

˜Polyester Resin˜

As the polyester resin, for example, polyethylene terephthalate (PET) and polyethylene-2,6-naphthalate (PEN) are preferable.

As the polyester resin, a commercially available product which is released may be used. For example, VYLONAL (registered trademark) MD-1245 (manufactured by Toyobo Co., Ltd.) may be preferably used.

˜Polyurethane Resin˜

As the polyurethane resin, for example, a carbonate-based urethane resin is preferable, and for example, SUPERFLEX (registered trademark) 460 (manufactured by DKS Co. Ltd.) may be preferably used.

˜Polyolefin Resin˜

As the polyolefin resin, for example, a modified polyolefin copolymer is preferable. As the polyolefin resin, a commercially available product which is released may be used. Examples thereof include ELEVES (registered trademark) SE-1013N, SD-1010, TC-4010, TD-4010 (all manufactured by Unitika Ltd.), HITECH S3148, S3121, S8512 (all manufactured by TOHO CHEMICAL INDUSTRY Co., Ltd.), and CHEMIPEARL (registered trademark) S-120, S-75N, V100, and EV210H (all manufactured by Mitsui chemicals, Inc.). Among these, it is preferable to use ELEVES (registered trademark) SE-1013N manufactured by Unitika Ltd., which is a terpolymer of low-density polyethylene, acrylic acid ester, and maleic anhydride, in terms of adhesiveness enhancement.

In addition, an acid-modified polyolefin resin described in paragraphs “0022” to “0034” of JP2014-76632A may be preferably used.

—Other Additives—

Examples of other additives include a crosslinking agent for improving film hardness, a surfactant for improving coating film uniformity, an antioxidant, and a preservative depending on a function to be imparted to the undercoat layer.

˜Crosslinking Agent˜

The undercoat layer forming composition preferably includes a crosslinking agent.

When the undercoat layer forming composition includes a crosslinking agent, a crosslinking structure is formed in the resin component included in the undercoat layer forming composition, and a layer having further-improved adhesiveness and strength is formed.

As the crosslinking agent, an epoxy-based crosslinking agent, an isocyanate-based crosslinking agent, a melamine-based crosslinking agent, a carbodiimide-based crosslinking agent, an oxazoline-based crosslinking agent, and the like may be employed. From the viewpoint of ensuring adhesiveness between the undercoat layer and the polyester base material after exposure to moisture and heat for a period of time, an oxazoline-based crosslinking agent among these is particularly preferable.

Specific examples of the oxazoline-based crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethyl ene-bis-(2-oxazoline), 2,2′-octamethylene-bis-(2-oxazoline), 2,2′-ethylene-bis-(4,4′-dimethyl-2-oxazoline), 2,2′-p-phenyl ene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane)sulfide, and bis-(2-oxazolinylnorbornane)sulfide. Furthermore, (co)polymers of these compounds may also be preferably used.

As the oxazoline-based crosslinking agent, a commercially available product which is released may be used. For example, EPOCROS (registered trademark) K2010E, K2020E, K2030E, WS500, and WS700 [all manufactured by Nippon Shokubai Co., Ltd.] may be used.

As the crosslinking agent, only one kind of crosslinking agent may be used, or a combination of two or more kinds of crosslinking agent may be used.

The amount of the crosslinking agent added is preferably in a range of 1 parts by mass to 30 parts by mass with respect to 100 parts by mass of the resin component, and is more preferably in a range of 5 parts by mass to 25 parts by mass.

˜Catalyst for Crosslinking Agent˜

In the undercoat layer forming composition, the crosslinking agent and a catalyst for the crosslinking agent may be used in combination. When the catalyst for the crosslinking agent is included, a crosslinking reaction between the resin component and the crosslinking agent is accelerated, and an improvement in the solvent resistance is achieved. In addition, as the crosslinking reaction favorably proceeds, the strength and dimensional stability of the undercoat layer can be further improved.

Particularly, in a case where a crosslinking agent having an oxazoline group (oxazoline-based crosslinking agent) is used as the crosslinking agent, a catalyst for the crosslinking agent may be used.

As the catalyst for the crosslinking agent, onium compounds may be employed.

As the onium compounds, ammonium salts, sulfonium salts, oxonium salts, iodonium salts, phosphonium salts, nitronium salts, nitrosonium salts, diazonium salts, and the like may be suitably employed.

Specific examples of the onium compound include: ammonium salts such as ammonium monophosphate, ammonium diphosphate, ammonium chloride, ammonium sulfate, ammonium nitrate, ammonium p-toluenesulfonate, ammonium sulfamate, ammonium imidodisulfonate, tetrabutylammonium chloride, benzyltrimethylammonium chloride, triethylbenzyl ammonium chloride, tetrabutyl ammonium tetrafluoroborate, tetrabutyl ammonium hexafluorophosphate, tetrabutylammonium perchlorate, and tetrabutyl ammonium sulfate;

sulfonium salts such as trimethylsulfonium iodide, trimethylsulfonium tetrafluoroborate, diphenylmethylsulfonium tetrafluoroborate, benzyltetramethylenesulfonium tetrafluoroborate, 2-butenyltetramethylenesulfonium hexafluoroantimonate, and 3-methyl-2-butenyltetramethylenesulfonium hexafluoroantimonate;

oxonium salts such as trimethyloxonium tetrafluoroborate;

iodonium salts such as diphenyliodonium chloride and diphenyliodonium tetrafluoroborate;

phosphonium salts such as cyanomethyltributylphosphonium hexafluoroantimonate and ethoxycarbonylmethyltributylphosphonium tetrafluoroborate;

nitronium salts such as nitronium tetrafluoroborate;

nitrosonium salts such as nitrosonium tetrafluoroborate; and

diazonium salts such as 4-methoxybenzenediazonium chloride.

Among these, in terms of shortening the curing time, the onium compounds are more preferably the ammonium salts, the sulfonium salts, the iodonium salts, and the phosphonium salts. Among these, the ammonium salts are more preferable. From the viewpoint of safety, pH, and costs, phosphoric acid-based onium compounds and benzyl chloride-based onium compounds are preferable. The onium compound is particularly preferably ammonium diphosphate.

As the catalyst for the crosslinking agent, only one kind of catalyst may be used, and a combination of two or more kinds of catalyst may be used.

The amount of the catalyst for the crosslinking agent added is preferably, with respect to the crosslinking agent, in a range of 0.1 mass % to 15 mass %, more preferably in a range of 0.5 mass % to 12 mass %, particularly preferably in a range of 1 mass % to 10 mass %, and more particularly preferably 2 mass % to 7 mass %. An added amount of the catalyst for the crosslinking agent of 0.1 mass % or more with respect to the crosslinking agent means that the catalyst for the crosslinking agent is actively included. Due to the inclusion of the catalyst for the crosslinking agent, a crosslinking reaction between a polymer as a binder and the crosslinking agent more favorably proceeds, and superior solvent resistance is obtained, thereby obtaining better durability. In addition, when the content of the catalyst for the crosslinking agent is 15 mass % or less, there is an advantage in terms of solubility, filterability of a coating liquid, and adhesiveness between layers adjacent to each other.

In this disclosure, in order to enhance productivity in the inline coating method, that is, a film production speed, the aqueous dispersion may include a non-volatile aqueous aid such as a surfactant and an emulsifier. By selecting an appropriate non-volatile aqueous aid, both productivity and various performances can be more effectively achieved.

Here, the non-volatile aqueous aid means a non-volatile compound that contributes to dispersion and stabilization of the resin. As the non-volatile aqueous aid, a cationic surfactant, an anionic surfactant, a nonionic surfactant, an amphoteric surfactant, a fluorine-based surfactant, a reactive surfactant, a water soluble polymer, and the like may be employed. The non-volatile aqueous aid also includes those generally used for emulsion polymerization, and emulsifiers. Particularly, a fluorine-based surfactant and a nonionic surfactant are preferable.

Since the fluorine-based surfactant and the nonionic surfactant are nonionic and do not function as a catalyst for decomposition of the polyester, excellent weather resistance is achieved. The amount of the surfactant added is preferably, with respect to the aqueous dispersion, 1 ppm to 100 ppm, more preferably 5 ppm to 70 ppm, and particularly preferably 10 ppm to 50 ppm.

[Production Method of Laminated Polyester Film]

A method of producing the base material film used in this disclosure is not particularly limited, and for example, a method including: a process of stretching an un-stretched polyester film including polyester, inorganic particles as a whitening agent, and the like in a first direction; a process of applying an undercoat layer forming composition onto one surface of the polyester film stretched in the first direction as necessary; a process of stretching the resultant in a second direction perpendicular to the first direction; and a heat setting process of carrying out a heat setting treatment at 175° C. or higher and 230° C. or lower.

(Process of Stretching Un-Stretched Polyester Film in First Direction)

The un-stretched polyester film is stretched in the first direction.

Regarding the un-stretched polyester film, for example, using the polyester and the inorganic particles such as titanium oxide described above as raw materials, the raw materials are dried and are thereafter melted. The obtained melt is caused to pass through a gear pump or a filter and is thereafter extruded through a die into a cooling roll to cool and solidify, thereby obtaining the un-stretched polyester film. The melting is carried out using an extruder. A single-screw extruder may be used or a double-screw extruder may be used.

The extrusion is preferably carried out in a vacuum or in an inert gas atmosphere. The temperature of the extruder is preferably the melting point of the polyester being used to the melting point+80° C. or lower, more preferably the melting point+10° C. or higher and the melting point+70° C. or lower, and even more preferably the melting point+20° C. or higher and the melting point+60° C. or lower. When the temperature of the extruder is the melting point+10° C. or higher, the resin is sufficiently melted. On the other hand, when the temperature of the extruder is the melting point+70° C. or lower, decomposition of the polyester is suppressed, which is preferable. It is preferable to dry the raw resin material of the polyester before being extruded, and the moisture content thereof is preferably 10 ppm to 300 ppm and more preferably 20 ppm to 150 ppm.

For the purpose of improving the hydrolysis resistance of the un-stretched white polyester film, at least one of a ketenimine compound or a carbodiimide compound may be added when the raw resin material is melted.

The carbodiimide compound or the ketenimine compound may be directly added to the extruder. However, it is preferable to form masterbatch with the polyester in advance to be introduced into the extruder from the viewpoint of extrusion stability. In a case where the masterbatch is formed, it is preferable to vary the supply amount of the masterbatch including the ketenimine compound. Regarding the concentration of the ketenimine compound in the masterbatch, a concentrated ketenimine compound is preferably used. A ketenimine compound concentrated to 2 times to 100 times the concentration in a film after film production, and more preferably concentrated to 5 times to 50 times is preferably used from the viewpoint of costs.

The extruded melt is caused to pass through a gear pump, a filter, and a multi-layer die and flow onto a casting drum. As the type of the multi-layer die, either a multi-manifold die or a feedblock die may be suitably used. The shape of the die may be any of a T die, a coat-hanger die, and a fishtail die. It is preferable to change the temperature at the distal end (die lip) of the die. On the casting drum, the melted resin (melt) may be caused to come into close contact with the cooling roll using an electrostatic application method. At this time, it is preferable to change the driving speed of the casting drum as described above. The surface temperature of the casting drum may be set to approximately 10° C. to 40° C. The diameter of the casting drum is preferably 0.5 m or greater and 5 m or lower, and more preferably 1 m or greater and to 4 m or lower. The driving speed of the casting drum (the linear speed of the outermost circumference) is preferably 1 m/min or higher and 50 m/min or lower, and more preferably 3 m/min or higher and 30 m/min or lower.

In this disclosure, the un-stretched white polyester film which is formed by the above-described method or the like is subjected to a stretching treatment. The stretching is carried out in one of a machine direction (MD) and a transverse direction (TD). The stretching treatment may be either MD stretching or TD stretching.

The stretching treatment is carried out preferably at a temperature of the glass transition temperature (Tg: in the unit of ° C.) of the polyester film or higher and (Tg+60° C.) or lower, more preferably at a temperature of (Tg+3° C.) or higher and (Tg+40° C.) or lower, and even more preferably (Tg+5° C.) or higher and (Tg+30° C.) or lower.

The stretching ratio in at least one of the directions is preferably 270% to 500%, more preferably 280% to 480%, and even more preferably 290% to 460%. The stretching ratio mentioned here is obtained using the following expression.

Stretching ratio (%)=100×{(length after stretching)/(length before stretching)}

The uniaxially stretched white polyester film can be obtained through the above processes.

(Process of Applying Undercoat Layer Forming Composition)

Next, the undercoat layer forming composition is applied onto one surface of the white polyester film stretched in the first direction as necessary.

The application is preferable because a thin film with high uniformity can be simply formed. As an application method, for example, a well-known method using a gravure coater, a bar coater, or the like may be used. As a solvent for the undercoat layer forming composition used in the application, water may be used, or an organic solvent such as toluene or methyl ethyl ketone may be used. As the solvent, one kind of solvent may be singly used, or a mixture of two or more kinds of solvent may be used.

The application of the undercoat layer forming composition onto the uniaxially oriented film is preferably carried out inline subsequent to the process of stretching the un-stretched polyester film in the first direction.

Before the application of the undercoat layer forming composition, it is also preferable to carry out a surface treatment such as a corona discharge treatment, a glow treatment, an atmospheric pressure plasma treatment, a flame treatment, or an UV treatment on the uniaxially oriented film.

After the application of the undercoat layer forming composition, it is preferable to provide a process of drying the coating film. The drying process is a process of supplying dry air to the coating film. The average wind speed of the dry air is preferably 5 m/sec to 30 m/sec, more preferably 7 m/sec to 25 m/sec, and even more preferably 9 m/sec to 20 m/sec.

It is preferable that the drying of the coating film serves as a heat treatment.

(Process of Stretching Polyester Film in Second Direction)

The white polyester film to which the undercoat layer forming composition is applied as necessary is stretched in the second direction perpendicular to the first direction along the film surface.

As the polyester film is stretched in the second direction, the uniaxially stretched polyester film is stretched along with the undercoat layer forming composition, thereby obtaining a white polyester film coated with the undercoat layer (inline coating layer).

The stretching may be carried out in either the machine direction (MD) or the transverse direction (TD) as long as the direction is perpendicular to the first direction.

A preferable aspect of the process of stretching the polyester film in the second direction is the same as the process of the stretching the un-stretched polyester film in the first direction.

(Heat Setting Process)

The biaxially stretched white polyester film is subjected to the heat setting treatment.

In the heat setting process, a heat treatment is carried out on the film at a temperature of 175° C. or higher and 230° C. or lower, and preferably 180° C. or higher and 220° C. or lower (more preferably 185° C. or higher and 210° C. or lower) for 1 second to 60 seconds (more preferably 2 seconds to 30 seconds).

When the heat setting temperature is 180° C. or higher, heat setting is sufficiently achieved during the production of the white polyester film as the base material film (A), and thus the base material film (A) is less likely to absorb heat. Therefore, when the solar cell rear surface protective sheet according to this disclosure is attached to the sealing material with a pressure, generation of stress between the sealing material and the second resin layer (C) due to thermal shrinkage of the base material film (A) is suppressed, and stress generated during an adhesion test is relieved. Accordingly, adhesion is less likely to decrease. On the other hand, when the heat setting temperature is 220° C. or lower, the amount of carboxyl group generated due to pyrolysis during the production of the film is small, and thus a reduction in weather resistance (hydrolysis resistance) is suppressed. The heat setting temperature mentioned here is a film surface temperature during the heat setting treatment.

In the heat setting process provided after the stretching process, a portion of a volatile basic compound having a boiling point of 200° C. or lower may be caused to sublimate.

It is preferable that the heat setting process is carried out subsequent to the cross-direction stretching in a state where the polyester film is gripped by chucks in a tenter. At this time, the interval between the chucks may be the width at the time of the end of the cross-direction stretching. Otherwise, the interval may be widened, or the interval may be narrowed. When the heat setting process is carried out, fine crystals are generated, and mechanical characteristics or durability can be improved.

It is preferable to carry out a thermal relaxation process subsequent to the heat setting process. The thermal relaxation process refers to a process of contracting the film by applying heat to the film for stress relaxation. In the thermal relaxation process, relaxation is preferably carried out in at least one of the machine direction or the transverse direction. The relaxation ratio in both the machine direction and the transverse direction is preferably 1% to 15% (the ratio to the width after the cross-direction stretching), more preferably 2% to 10%, and even more preferably 3% to 8%. The relaxation temperature is preferably Tg+50° C. to Tg+180° C., more preferably Tg+60° C. to Tg+150° C., and even more preferably Tg+70° C. to Tg+140° C.

In the thermal relaxation process, in a case where the melting point of the polyester is referred to as Tm, the thermal relaxation treatment is carried out preferably at Tm−100° C. to Tm−10° C., more preferably Tm−80° C. to Tm−20° C., and even more preferably Tm−70° C. to Tm−35° C. Accordingly, the generation of crystals is accelerated, and mechanical strength and heat-shrinkable properties are improved. Furthermore, the hydrolysis resistance is improved by the thermal relaxation treatment at Tm−35° C. or lower. This is because the reactivity with water is suppressed by increasing tension (binding) without disturbing the orientation of amorphous portions where hydrolysis easily occurs.

Relaxation in the transverse direction may be carried out by narrowing the width of clips of the tenter. In addition, relaxation in the machine direction may be carried out by narrowing the interval between adjacent clips of the tenter. This can be achieved by connecting the adjacent clips in a pantograph shape and narrowing the pantograph. In addition, the film may be relaxed by being subjected to a heat treatment while being transported with low tension after being taken out of the tenter. The tension is preferably 0 N/mm² to 0.8 N/mm² per cross-sectional area of the film, more preferably 0 N/mm² to 0.6 N/mm², and even more preferably 0 N/mm² to 0.4 N/mm². A tension of 0 N/mm² can be realized by providing two or more pairs of nip rollers during transportation and loosening the film therebetween (in a suspended form).

Both ends of the film taken out of the tenter, which are gripped by the clips, are trimmed, and after both ends are subjected to knurling (press working), the film is wound. The width of the film is preferably 0.8 m to 10 m, more preferably 1 m to 6 m, and even more preferably 1.5 m to 4 m. The thickness of the film is preferably 30 μm to 300 μm, more preferably 40 μm to 280 μm, and even more preferably 45 μm to 260 μm. The adjustment of the thickness of the film can be achieved by adjusting the discharge amount of the extruder, or adjusting the film production speed (adjusting the speed of the cooling roll, the stretching speed connected thereto, and the like).

A film for recycling, such as the edge portion of the trimmed film, is recovered as a resin mixture and is recycled. The film for recycling becomes a raw film material of a white polyester film for the next lot, and is returned to the drying process as described above such that the production processes are sequentially repeated.

The solar cell rear surface protective sheet of this disclosure is configured by sequentially laminating a first resin layer (B) and a second resin layer (C) described below on the white polyester film. In a case where an undercoat layer is formed on one surface of the white polyester film as the base material film (A) by an inline coating method, the first resin layer (B) and the second resin layer (C) are sequentially laminated on the undercoat layer.

The solar cell rear surface protective sheet of this disclosure may have, as necessary, at least one functional layer such as a weather-resistant layer on the surface on the side opposite to the surface where the first resin layer (B) and the second resin layer (C) are provided.

For the application of the functional layer, a well-known application technique such as a roll coating method, a knife edge coating method, a gravure coating method, and a curtain coating method may be used.

In addition, before the application of these layers, the film may be subjected to a surface treatment (a flame treatment, a corona treatment, a plasma treatment, an ultraviolet treatment, or the like).

Furthermore, it is also preferable that the white polyester film and the functional layers are attached to each other using a pressure sensitive adhesive.

[First Resin Layer (B)]

In the solar cell rear surface protective sheet of this disclosure, a first resin layer (B) having a modulus of elasticity of 1.2 GPa or higher and 3.0 GPa or lower and a thickness of 1 μm or greater is laminated on one surface of the base material film (A) including the white polyester film. In a case where the base material film (A) has the white polyester film and the undercoat layer, the first resin layer (B) is laminated on the undercoat layer.

(Modulus of Elasticity of First Resin Layer (B))

When the modulus of elasticity of the first resin layer (B) is lower than 1.2 GPa, the modulus of elasticity is insufficient to withstand stress exerted on the first resin layer (B) when a 180° peel test is conducted on the solar cell rear surface protective sheet. Accordingly, the first resin layer (B) cracks and breaking of the film easily occurs.

On the other hand, when the modulus of elasticity of the first resin layer (B) is higher than 3.0 GPa, it is difficult to form the first resin layer (B) through bar coating, and although the first resin layer (B) can be formed through coextrusion, costs are significantly increased.

The modulus of elasticity of the first resin layer (B) in this disclosure can be measured by the following method.

A first resin layer forming composition is applied to a polyethylene terephthalate (PET) film (CERAPEEL (registered trademark) manufactured by Toray Industries, Inc.) treated by a release agent so as to cause the thickness thereof after being dried to reach 15 μm and is dried at 170° C. for two minutes, thereby forming a first resin layer (B) on the PET film.

The first resin layer (B) is cut into a size of 3 cm×5 mm, and the first resin layer (B) is peeled away from the PET film.

A tensile test for the first resin layer (B) is conducted on the obtained first resin layer (B) using a tensile tester (TENSILON manufactured by A&D Company) in an environment with a temperature of 23.0° C. and a relative humidity of 50.0% at a rate of 50 mm/min, and the modulus of elasticity thereof is measured.

The first resin layer (B) is formed by applying a composition in which a resin component in the first resin layer (B) is dissolved in an organic solvent or dispersed in water (first resin layer forming coating liquid) on one surface of the base material film (A).

The resin component in the first resin layer (B) is not particularly limited as long as the modulus of elasticity thereof reaches 1.2 GPa or higher and 3.0 GPa or lower when adhered to the base material film (A), and may be an acrylic resin, an ester resin, or an olefin resin. From the viewpoint of obtaining high adhesiveness to the base material film (A), at least one of the acrylic resin or the ester-based resin is preferably included. The acrylic resin may be used in combination with another resin such as a polyolefin resin, a polyurethane resin, or a polyester resin.

The resin component in the first resin layer (B) may be a commercially available product which can be procured, and examples thereof include: acrylic resins such as AS-563A (manufactured by Daicel Finechem Ltd.), JURYMER (registered trademark) ET-410 and SEK-301 (both manufactured by Toagosei Co., Ltd.), and BONRON (registered trademark) XPS001 and BONRON (registered trademark) XPS002 (both manufactured by Mitsui chemicals, Inc.); polyester-based resins such as FINETEX (registered trademark) ES2200 (manufactured by DIC Corporation); and polyolefin resins such as ELEVES (registered trademark) SE-1013N, SD-1010, TC-4010, and TD-4010 (all manufactured by Unitika Ltd.), HITECH S3148, S3121, and S8512 (all manufactured by TOHO CHEMICAL INDUSTRY Co., Ltd.), and CHEMIPEARL (registered trademark) S-120, S-75N, V100, and EV210H (all manufactured by Mitsui chemicals, Inc.).

As the resin component in the first resin layer (B), only one kind of resin component may be used, or a mixture of two or more kinds of resin component may be used. However, it is preferable that the acrylic resin or the ester-based resin occupies 50 mass % or more in the total mass of the resin component in the first resin layer (B).

In addition to the resin component and the solvent or the dispersion medium, other additives may be included in the composition used to form the first resin layer (B), as necessary.

—Other Additives—

Examples of other additives include inorganic particles for improving film hardness, a crosslinking agent, a surfactant for improving coating film uniformity, a colorant, an ultraviolet absorber, an antioxidant, a preservative, and the like selected depending on a function to be imparted to the first resin layer (B).

—Inorganic Particles—

Inorganic particles may be included in the first resin layer (B) as the whitening agent. Examples thereof include: silica particles such as colloidal silica; metal oxide particles such as titanium dioxide, aluminum oxide, zirconium oxide, magnesium oxide, and tin oxide; inorganic carbonate particles such as calcium carbonate and magnesium carbonate; and metal compound particles such as barium sulfate. Among these, as the inorganic particles, colloidal silica, titanium oxide particles, aluminum oxide particles, zirconium oxide, and the like are preferably employed. The first resin layer (B) may include only one kind of inorganic particles or may also include two or more kinds thereof in combination.

Colloidal silica which can be used in the first resin layer (B) means an aspect in which particles primarily including a silicon oxide are present in a colloidal form using water, an alcohol, a diol, or a mixture thereof as a dispersion medium.

The volume average particle diameter of the colloidal silica particles is preferably several nm to 100 nm. The volume average particle diameter thereof can be measured by a particle diameter distribution meter utilizing a dynamic light scattering method or a static light scattering method, or the like. The shape of the colloidal silica particles may be a spherical shape, or may be a shape in which these particles are connected like beads.

The colloidal silica particles are commercially available, and examples thereof include SNOWTEX (registered trademark) series manufactured by Nissan Chemical Industries, Ltd., CATALOID (registered trademark) S series manufactured by JGC C&C, and LEVASIL series manufactured by Bayer AG. Specific examples thereof include: SNOWTEX (registered trademark) ST-20, ST-30, ST-40, ST-C, ST-N, ST-20L, ST-O, ST-OL, ST-S, ST-XS, ST-XL, ST-YL, ST-ZL, ST-OZL, and ST-AK manufactured by Nissan Chemical Industries, Ltd., SNOWTEX (registered trademark) AK series, SNOWTEX (registered trademark) PS series, and SNOWTEX (registered trademark) UP series.

In addition, examples of commercially available titanium oxide particles that can be used in the first resin layer (B) include TIPAQUE (registered trademark) CR-95, manufactured by Ishihara Sangyo Kaisha, Ltd.

The volume average particle diameter of the inorganic particles included in the first resin layer (B) is not particularly limited. However, from the viewpoint of improving film hardness and maintaining favorable adhesiveness, the volume average particle diameter is preferably equal to or smaller than the thickness of the first resin layer (B), more preferably equal to or smaller than ½ of the thickness of the first resin layer (B), and even more preferably equal to or smaller than ⅓ of the thickness of the first resin layer (B).

In addition, specifically, the volume average particle diameter of the inorganic particles is preferably 0.1 μm or smaller, more preferably 10 nm to 700 nm, and even more preferably 15 nm to 300 nm.

In this disclosure, as the volume average particle diameter of the inorganic particles, a value measured by MICROTRAC FRA manufactured by Honeywell International, Inc. is used.

The content of the inorganic particles in the first resin layer (B) is preferably in a range of 10 vol % to 35 vol % and more preferably in a range of 20 vol % to 30 vol %.

—Crosslinking Agent—

The resin component included in the first resin layer (B) may be cross-linked with a crosslinking agent. When a crosslinking structure is formed in the first resin layer (B), adhesiveness can be further improved, which is preferable. As the crosslinking agent, crosslinking agents exemplified for the undercoat layer, such as epoxy-based, isocyanate-based melamine-based, carbodiimide-based, and oxazoline-based crosslinking agents may be employed.

—Catalyst for Crosslinking Agent—

Even in the first resin layer (B), in a case where the crosslinking agent is used, a catalyst for the crosslinking agent may be further used in combination. When the catalyst for the crosslinking agent is included, a crosslinking reaction between the resin component and the crosslinking agent is accelerated, and an improvement in the solvent resistance is achieved. In addition, as the crosslinking reaction favorably proceeds, adhesiveness between the first resin layer (B) and the undercoat layer, or between the first resin layer (B) and the second resin layer (C), which will be described later, can be further improved.

Particularly, in a case where a crosslinking agent having an oxazoline group (oxazoline-based crosslinking agent) is used as the crosslinking agent, a catalyst for the crosslinking agent may be used.

As the catalyst for the crosslinking agent, an onium compound may be employed.

As the onium compound, ammonium salts, sulfonium salts, oxonium salts, iodonium salts, phosphonium salts, nitronium salts, nitrosonium salts, diazonium salts, and the like may be suitably employed.

As the catalyst for the crosslinking agent, the same compounds as those that are employed by the undercoat layer may be used, and preferable examples are also the same.

—Thickness of First Resin Layer (B)—

The thickness of the first resin layer (B) is 1 μm or greater. When the thickness of the first resin layer (B) is smaller than 1 μm, the thickness is insufficient to withstand stress exerted on the first resin layer (B). Accordingly, the first resin layer (B) cracks and breaking of the film easily occurs. From the viewpoint of preventing breaking of the film, the thickness of the first resin layer (B) is preferably 3 μm or greater.

On the other hand, the thickness of the first resin layer is preferably 8 μm or smaller. When the thickness of the first resin layer (B) is 8 μm or smaller, it is difficult for stress exerted on the first resin layer (B) to increase, and peeling is less likely to occur in the first resin layer (B).

—Method of Forming First Resin Layer (B)—

The first resin layer (B) is formed on the undercoat layer through application. The application method is preferable because a thin film with high uniformity can be simply formed. As the application method, for example, a well-known method using a gravure coater, a bar coater, or the like may be used.

When the first resin layer (B) is formed through application, it is preferable to carry out both drying of the coating film and a heat treatment in a drying zone.

After the application of the composition used to form the first resin layer (B), it is preferable to provide a process of drying the coating film. The drying process is a process of supplying dry air to the coating film. The average wind speed of the dry air is preferably 5 m/sec to 30 m/sec, more preferably 7 m/sec to 25 m/sec, and even more preferably 9 m/sec to 20 m/sec.

[Second Resin Layer (C)]

The second resin layer (C) having a lower modulus of elasticity than that of the first resin layer (B) is provided on the first resin layer (B), that is, on the surface of the first resin layer (B) on the side opposite to the white polyester film. The second resin layer (C) is a layer which is positioned at a position that directly comes into contact with the sealing material of the solar cell module to which the solar cell rear surface protective sheet of this disclosure is applied, that is, at the outermost layer and functions as an easy-adhesion layer.

(Modulus of Elasticity of Second Resin Layer (C))

The modulus of elasticity of the second resin layer (C) needs to be lower than that of the first resin layer, and is preferably 150 MPa or lower and more preferably 80 MPa or lower. When the modulus of elasticity of the second resin layer (C) is 150 MPa or lower, elongation of the second resin layer (C) during an adhesion test becomes sufficient to achieve an improvement in adhesion.

Measurement of the modulus of elasticity of the second resin layer (C) can be carried out in the same manner as in the measurement of the modulus of elasticity of the first resin layer (B).

The second resin layer (C) includes at least a resin component and may include a variety of additives as desired. The modulus of elasticity of the second resin layer (C) can be adjusted by, as well as the kind of the resin component for forming the second resin layer (C), the kinds of the crosslinking agent and the catalyst and the amounts thereof added.

The resin component in the second resin layer (C) is not particularly limited as long as the modulus of elasticity of the second resin layer (C) becomes lower than the modulus of elasticity of the first resin layer when the resin component comes into contact with the first resin layer, and may be one or more kinds of polymer selected from a polyolefin resin, an acrylic resin, a polyester resin, and a polyurethane resin.

From the viewpoint of improving adhesiveness to EVA which is generally used as the sealing material, the second resin layer (C) preferably includes an olefin-based resin, and the olefin-based resin preferably occupies 50 mass % or more in the total mass of the resin component in the second resin layer (C).

Specifically, for example, resins described below may be employed.

As the acrylic resin, for example, a polymer including polymethyl methacrylate, polyethyl acrylate, or the like is preferable. As the acrylic resin, a composite resin of acryl and silicone is also preferable. As the acrylic resin, a commercially available product which is released may be used. Examples thereof include AS-563A (manufactured by Daicel FineChem Ltd.), and JURYMER (registered trademark) ET-410 and JURYMER SEK-301 (both manufactured by Toagosei Co., Ltd.). As the composite resin of acryl and silicone, CERANATE (registered trademark) WSA1060 and WSA1070 (both manufactured by DIC Corporation), and H7620, H7630, and H7650 (all manufactured by Asahi Kasei Corporation).

As the polyester resin, for example, polyethylene terephthalate (PET) and polyethylene-2,6-naphthalate (PEN) are preferable. As the polyester resin, a commercially available product which is released may be used. For example, VYLONAL (registered trademark) MD-1245 (manufactured by Toyobo Co., Ltd.) may be preferably used.

As the polyurethane resin, for example, a carbonate-based urethane resin is preferable, and for example, SUPERFLEX (registered trademark) 460 (manufactured by DKS Co. Ltd.) may be preferably used.

As the olefin-based resin, for example, a modified polyolefin copolymer is preferable. As the polyolefin resin, a commercially available product which is released may be used. Examples thereof include ELEVES (registered trademark) SE-1013N, SD-1010, TC-4010, TD-4010 (all manufactured by Unitika Ltd.), HITECH S3148, S3121, S8512 (all manufactured by TOHO CHEMICAL INDUSTRY Co., Ltd.), and CHEMIPEARL (registered trademark) S-120, S-75N, V100, and EV210H (all manufactured by Mitsui chemicals, Inc.). Among these, it is preferable to use ELEVES (registered trademark) SE-1013N (manufactured by Unitika Ltd.), which is a terpolymer of low-density polyethylene, acrylic acid ester, and maleic anhydride, in terms of adhesion improvement.

These olefin-based resins may be used singly or in a combination of two or more kinds thereof. In a case where of a combination of two or more kinds thereof, a combination of an acrylic resin and an olefin-based resin, a combination of a polyester resin and an olefin-based resin, or a combination of a urethane resin and an olefin-based resin is preferable and a combination of an acrylic resin and an olefin-based resin is more preferable.

In a case where a combination of an acrylic resin and an olefin-based resin is used, the content of the acrylic resin with respect to the total amount of the olefin-based resin and the acrylic resin in the second resin layer (C) is preferably 3 mass % to 50 mass %, more preferably 5 mass % to 40 mass %, and particularly preferably 7 mass % to 25 mass %.

—Crosslinking Agent—

The resin component included in the second resin layer (C) may be cross-linked with a crosslinking agent. When a crosslinking structure is formed in the second resin layer (C), adhesiveness can be further improved, which is preferable. As the crosslinking agent, crosslinking agents exemplified for the undercoat layer, such as epoxy-based, isocyanate-based, melamine-based, carbodiimide-based, and oxazoline-based crosslinking agents may be employed. Among these, it is preferable that the crosslinking agent in the second resin layer (C) is an oxazoline-based crosslinking agent. As the crosslinking agent having an oxazoline group, EPOCROS (registered trademark) K2010E, K2020E, K2030E, WS-500, and WS-700 (all manufactured by Nippon Shokubai Co., Ltd.) or the like may be used.

The amount of the crosslinking agent added is preferably 0.5 mass % to 50 mass % with respect to the resin component included in the second resin layer (C), more preferably 3 mass % to 40 mass %, and particularly preferably 5 mass % or more and less than 30 mass %. Particularly, when the amount of the crosslinking agent added is 0.5 mass % or more, a sufficient crosslinking effect is obtained while maintaining the strength and adhesiveness of the second resin layer (C). When the amount thereof is 50 mass % or less, the pot life of a coating liquid can be maintained for a long period of time. When the amount thereof is less than 40 mass %, the properties of a coating surface can be improved.

—Catalyst for Crosslinking Agent—

Even in the second resin layer (C), in a case where the crosslinking agent is used, a catalyst for the crosslinking agent may be further used in combination. When the catalyst for the crosslinking agent is included, a crosslinking reaction between the resin component and the crosslinking agent is accelerated, and an improvement in the solvent resistance is achieved. In addition, as the crosslinking reaction favorably proceeds, adhesiveness between the second resin layer (C) and the sealing material can be further improved.

Particularly, in a case where a crosslinking agent having an oxazoline group (oxazoline-based crosslinking agent) is used as the crosslinking agent, a catalyst for the crosslinking agent may be used.

As the catalyst for the crosslinking agent, an onium compound may be employed.

As the onium compound, ammonium salts, sulfonium salts, oxonium salts, iodonium salts, phosphonium salts, nitronium salts, nitrosonium salts, diazonium salts, and the like may be suitably employed.

As the catalyst for the crosslinking agent, the same compounds as those that are employed by the undercoat layer may be used, and preferable examples are also the same.

As the catalyst for the crosslinking agent included in the second resin layer (C), only one kind of catalyst may be used, and a combination of two or more kinds of catalyst may be used.

The amount of the catalyst for the crosslinking agent added is, with respect to the crosslinking agent, preferably in a range of 0.1 mass % to 15 mass %, more preferably in a range of 0.5 mass % to 12 mass %, particularly preferably in a range of 1 mass % to 10 mass %, and more particularly preferably 2 mass % to 7 mass %. An added amount of the catalyst for the crosslinking agent of 0.1 mass % or more with respect to the crosslinking agent means that the catalyst for the crosslinking agent is actively included. Due to the inclusion of the catalyst for the crosslinking agent, a crosslinking reaction between the resin component and the crosslinking agent more favorably proceeds, and superior solvent resistance is obtained. In addition, when the content of the catalyst for the crosslinking agent is 15 mass % or less, there is an advantage in terms of solubility, filterability of a coating liquid, and adhesiveness between the second resin layer (C) and the sealing material.

The second resin layer (C) may include a variety of additives in addition to the resin component as long as the effect of the embodiment of the present invention is not significantly hindered.

As the additives, an antistatic agent, an ultraviolet absorber, a colorant, a preservative, and the like may be employed.

As the antistatic agent, surfactants such as nonionic surfactants, organic conductive materials, inorganic conductive materials, and organic/inorganic composite conductive materials, and the like may be employed.

As the surfactants used as the antistatic agent included in the second resin layer (C), nonionic surfactants and anionic surfactants are preferable, and among these, nonionic surfactants are more preferable. A nonionic surfactant which has an ethylene glycol chain (polyoxyethylene chain —(CH₂—CH₂—O)ₙ—) but does not have a carbon-carbon triple bond (alkyne bond) is preferably employed. Furthermore, a nonionic surfactant having 7 to 30 ethylene glycol chains is particularly preferable.

More specifically, hexaethylene glycol monododecyl ether, 3,6,9,12,15-pentaoxahexadecan-1-ol, polyoxyethylene phenyl ether, polyoxyethylene methyl phenyl ether, polyoxyethylene naphthyl ether, polyoxyethylene methyl naphthyl ether, and the like may be employed. However, the surfactant is not limited thereto.

In a case where the surfactant is used as the antistatic agent, the content of the surfactant is, in terms of solid content concentration, preferably 2.5 mass % to 40 mass %, more preferably 5.0 mass % to 35 mass %, and even more preferably 10 mass % to 30 mass %.

With the content of the surfactant in the above-described range, the dropping of the partial discharge voltage is suppressed, and adhesiveness between a sealing material for sealing a solar cell element and a sealing material (for example, EVA: ethylene-vinyl acetate copolymer) is favorably maintained.

Examples of the organic conductive materials include: cationic conductive compounds having a cationic substituent such as an ammonium group, an amine base, or a quaternary ammonium group in the molecule; anionic conductive compounds having an anionic group such as a sulfonate salt group, a phosphate salt group, and a carboxylate salt group; ionic conductive materials such as amphoteric conductive compounds having both an anionic substituent and a cationic substituent; and conductive polymer compounds having a conjugated polyene-based skeleton, such as polyacetylene, poly-p-phenylene, polyaniline, polythiophene, poly-p-phenylene vinylene, and polypyrrole.

Examples of the inorganic conductive materials include: oxides, suboxides, and hypooxides of materials primarily containing a group of inorganic substances such as gold, silver, copper, platinum, silicon, boron, palladium, rhenium, vanadium, osmium, cobalt, iron, zinc, ruthenium, praseodymium, chromium, nickel, aluminum, tin, zinc, titanium, tantalum, zirconium, antimony, indium, yttrium, lanthanum, magnesium, calcium, cerium, hafnium, or barium; mixtures of the group of inorganic substances and oxides, suboxides, and hypooxides of the group of inorganic substances (hereinafter, collectively referred to as an inorganic oxide); nitrides, subnitrides, and hyponitrides of materials primarily containing the group of inorganic substances; mixtures of the group of inorganic substances and nitrides, subnitrides, hyponitrides of the group of inorganic substances (hereinafter, collectively referred to as an inorganic nitride); oxynitrides, suboxynitrides, and hypooxynitrides of materials primarily containing the group of inorganic substances; mixtures of the group of inorganic substances and oxynitrides, suboxynitrides, and hypooxynitrides of the group of inorganic substances (hereinafter, collectively referred to as an inorganic nitrude); carbides, subcarbides, and hypocarbides of materials primarily containing the group of inorganic substances; mixtures of the group of inorganic substances and carbides, subcarbides, and hypocarbides of the group of inorganic substances (hereinafter, collectively referred to as an inorganic carbide); halides, subhalides, and hypohalides of at least one of fluorides, chlorides, bromides, or iodides of materials primarily containing the group of inorganic substances; mixtures of the group of inorganic substances and halides, subhalides, and hypohalides of the group of inorganic substances (hereinafter, collectively referred to as an inorganic halide); mixtures of the group of inorganic substances and sulfides, subsulfides, and hyposulfides of the group of inorganic substances (which are hereinafter generically referred to as an inorganic sulfide); mateirals obtained by doping the group of inorganic substances with heteroelements; carbon-based compounds such as graphite carbon, diamond-like carbon, carbon fibers, carbon nanotubes, and fullerenes (hereinafter, collectively referred to as a carbon-based compound); and mixtures thereof.

(Thickness of Second Resin Layer (C))

The thickness of the second resin layer (C) is preferably 0.01 μm or greater and 1 μm or smaller, and more preferably 0.1 μm or greater and 0.6 μm or smaller. When the thickness of the second resin layer (C) is 0.01 μm or greater, the second resin layer (C) can be easily formed through bar coating. In addition, when thickness of the second resin layer (C) is 1 μm or smaller, stress exerted on the second resin layer (C) is less likely to increase, and peeling in the second resin layer (C) is less likely to occur.

—Method of Forming Second Resin Layer (C)—

The second resin layer (C) is formed by applying a composition in which the resin component in the second resin layer (C) is dissolved in an organic solvent or dispersed in water (second resin layer forming coating liquid) onto the first resin layer (B). The application method is preferable because a thin film with high uniformity can be simply formed. As the application method, for example, a well-known method using a gravure coater, a bar coater, or the like may be used.

When the second resin layer (C) is formed through application, it is preferable to carry out both drying of the coating film and a heat treatment in a drying zone.

After the application of the composition used to form the second resin layer (C), it is preferable to provide a process of drying the coating film. The drying process is a process of supplying dry air to the coating film. The average wind speed of the dry air is preferably 5 m/sec to 30 m/sec, more preferably 7 m/sec to 25 m/sec, and even more preferably 9 m/sec to 20 m/sec.

[Weather-Resistant Layer]

The solar cell rear surface protective sheet of this disclosure may have at least one weather-resistant layer on the side of the base material film (A) on which the first resin layer (B) and the second resin layer (C) are not provided. When the solar cell rear surface protective sheet has the weather-resistant layer, effects of environments on the base material are suppressed, and weather resistance and durability are further improved.

[Other Layers]

(Gas Barrier Layer)

A gas barrier layer may be provided on the surface of the base material film (white polyester film) opposite to the first resin layer (B). The gas barrier layer is a layer for imparting a moisture-proof function to prevent permeation of water or gas into the base material film.

The amount of water vapor permeating through the gas barrier layer (moisture permeability) is preferably 10² g/m²·day to 10⁻⁶ g/m²·day, more preferably 10¹ g/m²·day to 10⁻⁵ g/m²·day, and even more preferably 10° g/m²·day to 10⁴ g/m²·day.

In order to form the gas barrier layer having such moisture permeability, a dry method is suitable. As a method of forming the gas barrier layer having a gas barrier property using the dry method, a vacuum vapor deposition method such as resistance heating vapor deposition, electron beam vapor deposition, induced heating vapor deposition, and an assistance method in which plasma or ion beams are used for the above-mentioned methods; a sputtering method such as a reactive sputtering method, an ion beam sputtering method, and an electron cyclotron resonance (ECR) sputtering method; a physical vapor deposition method (PVD method) such as an ion plating method; and a chemical vapor deposition method (CVD method) in which heat, light, plasma, or the like is used may be employed. Among these, a vacuum vapor deposition method in which a film is formed using a vapor deposition method in a vacuum is preferable.

As a material for forming the gas barrier layer, an inorganic oxide, an inorganic nitride, an inorganic oxynitride, an inorganic halide, an inorganic sulfide, and the like may be employed.

An aluminum foil may also be attached so as to be used as the gas barrier layer.

The thickness of the gas barrier layer is preferably 1 μm or greater and 30 μm or smaller. When the thickness thereof is 1 μm or greater, the gas barrier layer does not easily allow water to permeate into the base material during a period of time (thermo) and excellent hydrolysis resistance is achieved. When the thickness thereof is 30 μm or smaller, an inorganic layer does not become excessively thick, and accretion in the base material due to stress in the inorganic layer does not occur.

<Solar Cell Module>

The solar cell module of this disclosure is configured to include the solar cell rear surface protective sheet of this disclosure described above.

Since the adhesiveness of the solar cell rear surface protective sheet of this disclosure described above, which is provided in the solar cell module of this disclosure, to the sealing material is excellent for a long period of time, the solar cell module of this disclosure can stably maintain power generation performance for a long period of time.

Specifically, the solar cell module of this disclosure is provided with an element structure portion which has a solar cell element and a sealing material that seals the solar cell element, a transparent substrate (a front base material such as a glass substrate) positioned on a side of the element structure portion on which sunlight is incident, and the solar cell rear surface protective sheet which is disposed on a side opposite to the side on which the substrate of the element structure portion is positioned and the second resin layer is adhered to the sealing material, and thus has a laminated structure made up of the transparent front base material, the element structure portion, and the protective sheet. Specifically, a configuration is achieved in which the element structure portion in which the solar cell element for converting the energy of sunlight into electrical energy is disposed is disposed between the transparent front base material disposed on the side on which sunlight is directly incident and the solar cell rear surface protective sheet of this disclosure, and the element structure portion (for example, a solar cell) including the solar cell element is sealed with and attached to the sealing material based on ethylene-vinyl acetate (EVA) or the like, between the front base material and the solar cell rear surface protective sheet. The solar cell rear surface protective sheet of this disclosure has excellent adhesiveness particularly to EVA, and an improvement in long-term durability can be achieved.

FIG. 2 schematically illustrates an example of a configuration of the solar cell module of this disclosure. A solar cell module 100 illustrated in FIG. 2 includes a transparent front substrate 24 on which sunlight is incident, a solar cell element 20, a sealing material 22 for sealing the solar cell element 20, and a solar cell rear surface protective sheet 10A disposed on a side of the sealing material 22 opposite to the front substrate 24. The solar cell rear surface protective sheet 10A has a configuration in which a second resin layer 16 side thereof is adhered to the sealing material 22 and two weather-resistant layers 18 and 19 are laminated on the surface on the opposite side.

Members other than the solar cell module, the solar cell, and the protective sheet are described in detail, for example, in “Solar Power System Constitutive Materials” (edited by EIICHI SUGIMOTO and published by KOGYO CHOSAKAI PUBLISHING in 2008).

The transparent base material may have a light-transmitting property so as to be capable of transmitting sunlight and may be appropriately selected from base materials that transmit light. From the viewpoint of power generation efficiency, it is preferable that the light transmittance is as high as possible, as such substrates, for example, a glass substrate and a transparent resin such as an acrylic resin may be suitably used.

Examples of the solar cell element include a variety of well-known solar cell elements such as a solar cell element based on silicon such as monocrystalline silicon, polycrystalline silicon, or amorphous silicon, or a solar cell element based on a III-V group or II-VI group compound semiconductor such as copper-indium-gallium-selenium, copper-indium-selenium, cadmium-tellurium, and gallium-arsenic. A space between the substrate and the polyester film may be configured to be sealed with a resin (so-called sealing material) such as an ethylene-vinyl acetate copolymer.

### EXAMPLES

Hereinafter, the present invention will be described in detail using examples, but the present invention is not limited to the following examples without departing from the gist of the present invention. In addition, unless otherwise defined, “parts” is based on mass.

—Synthesis of Polyester—

100 kg of high-purity terephthalic acid (manufactured by Mitsui Chemicals, Inc.) and 45 kg of a slurry of ethylene glycol (manufactured by Nippon Shokubai Co., Ltd.) were sequentially supplied for four hours to an esterification reactor which was charged with about 123 kg of bis(hydroxyethyl)terephthalate, and the resultant was subjected to an esterification reactor held at a temperature of 250° C. and a pressure of 1.2×10⁵ Pa for one hour after the supply. Thereafter, 123 kg of the obtained esterification reaction product was transported to a polycondensation reactor.

Subsequently, 0.3 mass % of ethylene glycol with respect to the obtained polymer was further added to the polycondensation reactor to which the esterification reaction product was transported. After five minutes of stirring, ethylene glycol solutions of cobalt acetate and manganese acetate were added to the obtained polymer so as to reach 30 ppm and 15 ppm, respectively. Furthermore, after five minutes of stirring, a 2 mass % ethylene glycol solution of a titanium alkoxide compound was added to the obtained polymer so as to reach 5 ppm. After five minutes, a 10 mass % ethylene glycol solution of ethyl diethylphosphonoacetate was added to the obtained polymer so as to reach 5 ppm. Thereafter, while stirring a low polymer at 30 rpm, the reaction system was gradually increased in temperature from 250° C. to 285° C. and was decreased in pressure to 40 Pa. The periods of time until the final temperature and the final pressure were reached were both set to 60 minutes. At a time point at which a predetermined stirring torque was reached, the reaction system was purged with nitrogen, the pressure was returned to normal pressure, and the polycondensation reaction was stopped. In addition, the polymer obtained by the above-described polycondensation reaction was discharged to cold water in a strand shape, was immediately cut into polymer pellets (with a diameter of about 3 mm and a length of about 7 mm). The period of time until the predetermined stirring torque was reached after the start of depressurization was 3 hours.

Here, as the titanium alkoxide compound, the titanium alkoxide compound (Ti content=4.44 mass %) synthesized in Example 1 of paragraph [0083] of JP2005-340616A was used.

—Solid-Phase Polymerization—

The pellets obtained as above, excluding pellets used to produce master pellets, which will be described later, were held at a temperature of 220° C. for 30 hours in a vacuum container held at 40 Pa, thereby causing solid-phase polymerization.

—Production of Master Pellets—

Titanium oxide was added to a portion of the pellets before the solid-phase polymerization so that the content thereof reached 50 mass % of the total amount of the pellets, and the resultant was kneaded, thereby producing master pellets.

Here, as the titanium oxide, PF-739 (trade name, average primary particle diameter=0.25 μm, subjected to a polyol treatment after an alumina treatment as a surface treatment) manufactured by Ishihara Sangyo Kaisha, Ltd. was used.

### Example 1

<Production of Solar Cell Rear Surface Protective Sheet>

—Production of Base Material Film (A)—

The pellets which had been subjected to solid-phase polymerization and the master pellets were mixed so as to cause the amount of titanium oxide to reach 4.4 mass %, the resultant was melted at 280° C. and was cast on a metallic drum, thereby producing an un-stretched polyethylene terephthalate (PET) film having a thickness of approximately 3 mm.

Thereafter, the un-stretched PET film was stretched 3.4 times in the machine direction (MD) at 90° C.

Next, an undercoat layer forming composition having the following composition was applied, using an inline coating method, onto the uniaxially oriented PET film stretched in the MD direction after the MD stretching but before transverse direction (TD) stretching so that the amount of the undercoat layer forming composition applied reached 5.1 ml/m².

(Composition of Undercoat Layer Forming Composition)

| | | |
|---|---|---|
| Water dispersion liquid of acrylic resin | 21.9 | parts by mass |
| [AS-563A, manufactured by Daicel FineChem | | |
| Ltd., a latex having a styrene skeleton | | |
| in a solid content of 28 mass %] | | |
| Water-soluble oxazoline-based crosslinking | 4.9 | parts by mass |
| agent | | |
| [EPOCROS (registered trademark) WS-700 | | |
| manufactured by Nippon Shokubai Co., | | |
| Ltd., solid content: 25 mass %] | | |
| Fluorine-based surfactant | 0.1 | parts by mass |
| Distilled water | 73.1 | parts by mass |

The PET film to which the undercoat layer forming composition was applied was stretched in the TD direction, thereby forming an undercoat layer having a thickness of 0.1 μm. The TD stretching was carried out under conditions with a temperature of 105° C. and a stretching ratio of 3.8 times.

The PET film in which the undercoat layer was formed was subjected to a heat setting treatment on a film surface at 190° C. for 15 seconds, and the resultant was subjected to a thermal relaxation treatment at 190° C. in the MD and TD directions at an MD relaxation ratio of 5% and a TD relaxation ratio of 11%, thereby obtaining a 250 μm-thick biaxially oriented white PET film (base material film (A)) in which the undercoat layer was formed.

The average particle diameter of the inorganic particles included in the base material film (A) was obtained as 0.23 μm by an electron microscopic method. The measurement of the average particle diameter is specifically based on the following method.

Particles were observed with a scanning electron microscope, and photographs taken by appropriately changing the magnification according to the size of the particles were enlarged and copied. Next, for at least 200 particles randomly selected, the outer circumference of each of the particles was traced. The equivalent circle diameters of the particles were measured from the traced images by an image analyzer, and the average value thereof is determined as the average particle diameter.

A first resin layer (B) and a second resin layer (C) were sequentially formed on the undercoat layer side of the base material film (A) obtained as described above (hereinafter, referred to as “white PET film”), in the following manner.

First, a first resin layer forming composition was prepared to have the composition described below.

—First resin layer Forming Composition (B1) of Example 1—

| | | |
|---|---|---|
| Water dispersion liquid of acrylic resin | 40.8 | parts by mass |
| [AS-563A, manufactured by Daicel FineChem | | |
| Ltd., a latex having a styrene skeleton | | |
| in a solid content of 28 mass %] | | |
| Water-soluble oxazoline-based crosslinking | 11.4 | parts by mass |
| agent | | |
| [EPOCROS (registered trademark) WS-700 | | |
| manufactured by Nippon Shokubai Co., | | |
| Ltd., solid content: 25 mass %] | | |
| Ammonium diphosphate (solid content: 35.0 | 0.9 | parts by mass |
| mass %) | | |
| Fluorine-based surfactant (solid content: | 1.0 | parts by mass |
| 2.0 mass %) | | |
| Distilled water | 45.9 | parts by mass |

The obtained first resin layer forming composition was applied onto the surface of the white PET film on which the undercoat layer was formed so that the thickness (dry thickness) after drying reached 5 μm, and the resultant was dried at 170° C. for two minutes, thereby forming a first resin layer (B).

Thereafter, the second resin layer forming composition (C1) having the following composition was applied onto the surface of the first resin layer (B) so that the thickness after drying reached 0.4 μm, and the resultant was dried, thereby forming a second resin layer (C).

The composition of the second resin layer forming composition is as follows. EMALEX 110 was diluted in a mixed solvent of water and ethanol at a ratio of 2:1 to reach 10 mass %.

—Second Resin Layer Forming Composition (C1) of Example 1—

| | | |
|---|---|---|
| Water dispersion liquid of acrylic resin | 1.7 | parts by mass |
| [AS-563A, manufactured by Daicel FineChem | | |
| Ltd., a latex having a styrene skeleton | | |
| in a solid content of 28 mass %] | | |
| Water dispersion liquid of polyolefin | 9.4 | parts by mass |
| resin | | |
| [ELEVES (registered trademark) SE-1013N | | |
| manufactured by Unitika Ltd., solid | | |
| content: 20.2 mass %] | | |
| Water-soluble oxazoline-based crosslinking | 1.2 | parts by mass |
| agent | | |
| [EPOCROS (registered trademark) WS-700 | | |
| manufactured by Nippon Shokubai Co., | | |
| Ltd., solid content: 25 mass %] | | |
| Surfactant | 4.2 | parts by mass |
| [EMALEX (registered trademark) 110, | | |
| manufactured by Nihon Emulsion Co., Ltd., | | |
| solid content: 10 mass %] | | |
| Distilled water | 83.5 | parts by mass |

### Example 2

A solar cell rear surface protective sheet was produced in the same manner as in Example 1 except that a first resin layer forming composition (B2) described below was used instead of the first resin layer forming composition (B1) in Example 1.

—First Resin Layer Forming Composition (B2) of Example 2—

| | | |
|---|---|---|
| Polyester resin dispersion liquid | 38.1 | parts by mass |
| [FINETEX (registered trademark) ES2200, | | |
| manufactured by DIC Corporation, solid | | |
| content: 30 mass %] | | |
| Water-soluble oxazoline-based crosslinking | 11.4 | parts by mass |
| agent | | |
| [EPOCROS (registered trademark) WS-700 | | |
| manufactured by Nippon Shokubai Co., | | |
| Ltd., solid content: 25 mass %] | | |
| Ammonium diphosphate (solid content: 35.0 | 0.9 | parts by mass |
| mass %) | | |
| Fluorine-based surfactant (solid content: | 1.0 | parts by mass |
| 2.0 mass %) | | |
| Distilled water | 48.6 | parts by mass |

### Example 3

A solar cell rear surface protective sheet was produced in the same manner as in Example 1 except that a first resin layer forming composition (B3) described below was used instead of the first resin layer forming composition (B1) in Example 1.

—First Resin Layer Forming Composition (B3) of Example 3—

| | | |
|---|---|---|
| Water dispersion liquid of acrylic resin | 32.6 | parts by mass |
| [AS-563A, manufactured by Daicel FineChem | | |
| Ltd., a latex having a styrene skeleton | | |
| in a solid content of 28 mass %] | | |
| Water dispersion liquid of polyolefin | 11.3 | parts by mass |
| resin | | |
| [ELEVES (registered trademark) SE-1013N | | |
| manufactured by Unitika Ltd., solid | | |
| content: 20.2 mass %] | | |
| Water-soluble oxazoline-based crosslinking | 11.4 | parts by mass |
| agent | | |
| [EPOCROS (registered trademark) WS-700 | | |
| manufactured by Nippon Shokubai Co., | | |
| Ltd., solid content: 25 mass %] | | |
| Ammonium diphosphate (solid content: 35.0 | 0.9 | parts by mass |
| mass %) | | |
| Fluorine-based surfactant (solid content: | 1.0 | parts by mass |
| 2.0 mass %) | | |
| Distilled water | 42.8 | parts by mass |

### Example 4

A solar cell rear surface protective sheet was produced in the same manner as in Example 1 except that a first resin layer forming composition (B4) described below was used instead of the first resin layer forming composition (B1) in Example 1.

—First Resin Layer Forming Composition (B4) of Example 4—

| | | |
|---|---|---|
| Water dispersion liquid of acrylic resin | 37.4 | parts by mass |
| [AS-563A, manufactured by Daicel FineChem | | |
| Ltd., a latex having a styrene skeleton | | |
| in a solid content of 28 mass %] | | |
| Water-soluble oxazoline-based crosslinking | 10.5 | parts by mass |
| agent | | |
| [EPOCROS (registered trademark) WS-700 | | |
| manufactured by Nippon Shokubai Co., | | |
| Ltd., solid content: 25 mass %] | | |
| Ammonium diphosphate (solid content: 35.0 | 0.8 | parts by mass |
| mass %) | | |
| Titanium oxide dispersion liquid (solid | 8.4 | parts by mass |
| content: 49.0 mass %) | | |
| Fluorine-based surfactant (solid content: | 0.9 | parts by mass |
| 2.0 mass %) | | |
| Distilled water | 42.0 | parts by mass |

As the “titanium oxide dispersion liquid” described above, a titanium oxide dispersion liquid prepared in the following method was used.

˜Preparation of Titanium Oxide Dispersion Liquid˜

Titanium oxide having a volume average particle diameter of 0.42 μm was dispersed to achieve the following composition using a Dyno-Mill disperser, thereby preparing a titanium oxide dispersion liquid. The volume average particle diameter of the titanium oxide was measured using MICROTRAC FRA manufactured by Honeywell International, Inc.

˜Composition of Titanium Oxide Dispersion Liquid˜

| | | |
|---|---|---|
| Titanium oxide | 455.8 | parts by mass |
| [TIPAQUE (registered trademark) CR-95, | | |
| manufactured by Ishihara Sangyo Kaisha, | | |
| Ltd., powder)] | | |
| Polyvinyl alcohol (PVA) aqueous solution | 227.9 | parts by mass |
| [PVA-105, manufactured by Kuraray Co., | | |
| Ltd., solid content 10 mass %] | | |
| Dispersant | 5.5 | parts by mass |
| [DEMOL EP, manufactured by Kao | | |
| Corporation, solid content: 25 mass %)] | | |
| Distilled water | 287.5 | parts by mass |

### Examples 5 to 7

A solar cell rear surface protective sheet was produced in the same manner as in Example 1 except that the thickness of the first resin layer in Example 1 was changed as shown in Table 1.

### Example 8

A solar cell rear surface protective sheet was produced in the same manner as in Example 1 except that a second resin layer forming composition (C8) described below was used instead of the second resin layer forming composition (C1) in Example 1.

—Second Resin Layer Forming Composition (C8) of Example 8—

| | | |
|---|---|---|
| Water dispersion liquid of acrylic resin | 3.4 | parts by mass |
| [AS-563A, manufactured by Daicel FineChem | | |
| Ltd., a latex having a styrene skeleton | | |
| in a solid content of 28 mass %] | | |
| Water dispersion liquid of polyolefin resin | 7.1 | parts by mass |
| [ELEVES (registered trademark) SE-1013N | | |
| manufactured by Unitika Ltd., solid | | |
| content: 20.2 mass %] | | |
| Water-soluble oxazoline-based crosslinking | 1.2 | parts by mass |
| agent | | |
| [EPOCROS (registered trademark) WS-700 | | |
| manufactured by Nippon Shokubai Co., | | |
| Ltd., solid content: 25 mass %] | | |
| Surfactant | 4.2 | parts by mass |
| [EMALEX (registered trademark) 110, | | |
| manufactured by Nihon Emulsion Co., Ltd., | | |
| solid content: 10 mass %] | | |
| Distilled water | 84.1 | parts by mass |

### Example 9

A solar cell rear surface protective sheet was produced in the same manner as in Example 1 except that a second resin layer forming composition (C9) described below was used instead of the second resin layer forming composition (C1) in Example 1.

—Second Resin Layer Forming Composition (C9) of Example 9—

| | | |
|---|---|---|
| Water dispersion liquid of acrylic resin | 4.2 | parts by mass |
| [AS-563A, manufactured by Daicel FineChem | | |
| Ltd., a latex having a styrene skeleton | | |
| in a solid content of 28 mass %] | | |
| Water dispersion liquid of polyolefin resin | 5.9 | parts by mass |
| [ELEVES (registered trademark) SE-1013N | | |
| manufactured by Unitika Ltd., solid | | |
| content: 20.2 mass %] | | |
| Water-soluble oxazoline-based crosslinking | 1.2 | parts by mass |
| agent | | |
| [EPOCROS (registered trademark) WS-700 | | |
| manufactured by Nippon Shokubai Co., | | |
| Ltd., solid content: 25 mass %] | | |
| Surfactant | 4.2 | parts by mass |
| [EMALEX (registered trademark) 110, | | |
| manufactured by Nihon Emulsion Co., Ltd., | | |
| solid content: 10 mass %] | | |
| Distilled water | 84.5 | parts by mass |

### Examples 10 and 11

A solar cell rear surface protective sheet was produced in the same manner as in Example 1 except that the thickness of the second resin layer in Example 1 was changed as shown in Table 1.

### Examples 12 to 15

A solar cell rear surface protective sheet was produced in the same manner as in Example 1 except that the heat setting temperature during the production of the white PET film in Example 1 was changed as shown in Table 1.

### Comparative Example 1

A solar cell rear surface protective sheet was produced in the same manner as in Example 1 except that a first resin layer forming composition (b1) described below was used instead of the first resin layer forming composition (B1) in Example 1.

—First Resin Layer Forming Composition (b1) of Comparative Example 1—

| | | |
|---|---|---|
| Water dispersion liquid of polyolefin resin | 56.6 | parts by mass |
| [ELEVES (registered trademark) SE-1013N | | |
| manufactured by Unitika Ltd., solid | | |
| content: 20.2 mass %] | | |
| Water-soluble oxazoline-based crosslinking | 11.4 | parts by mass |
| agent | | |
| [EPOCROS (registered trademark) WS-700 | | |
| manufactured by Nippon Shokubai Co., | | |
| Ltd., solid content: 25 mass %] | | |
| Ammonium diphosphate (solid content: 35.0 | 0.9 | parts by mass |
| mass %) | | |
| Fluorine-based surfactant (solid content: | 1.0 | parts by mass |
| 2.0 mass %) | | |
| Distilled water | 30.1 | parts by mass |

### Comparative Example 2

A solar cell rear surface protective sheet was produced in the same manner as in Example 1 except that a first resin layer forming composition (b2) described below was used instead of the first resin layer forming composition (B1) in Example 1.

—First Resin Layer Forming Composition (b2) of Comparative Example 2—

| | | |
|---|---|---|
| Water dispersion liquid of acrylic resin | 20.4 | parts by mass |
| [AS-563A, manufactured by Daicel FineChem | | |
| Ltd., a latex having a styrene skeleton | | |
| in a solid content of 28 mass %] | | |
| Water dispersion liquid of polyolefin resin | 28.3 | parts by mass |
| [ELEVES (registered trademark) SE-1013N | | |
| manufactured by Unitika Ltd., solid | | |
| content: 20.2 mass %] | | |
| Water-soluble oxazoline-based crosslinking | 11.4 | parts by mass |
| agent | | |
| [EPOCROS (registered trademark) WS-700 | | |
| manufactured by Nippon Shokubai Co., | | |
| Ltd., solid content: 25 mass %] | | |
| Ammonium diphosphate (solid content: 35.0 | 0.9 | parts by mass |
| mass %) | | |
| Fluorine-based surfactant (solid content: | 1.0 | parts by mass |
| 2.0 mass %) | | |
| Distilled water | 38.0 | parts by mass |

### Comparative Example 3

A solar cell rear surface protective sheet was produced in the same manner as in Example 1 except that a first resin layer forming composition (b3) described below was used instead of the first resin layer forming composition (B1) in Example 1.

—First Resin Layer Forming Composition (b3) of Comparative Example 3—

| | | |
|---|---|---|
| Water dispersion liquid of styrene-acrylic | 25.4 | parts by mass |
| resin | | |
| [BONRON (registered trademark) XPS002 | | |
| manufactured by Mitsui chemicals, Inc., | | |
| solid content: 45 mass %, with a styrene | | |
| skeleton in the structure] | | |
| Water-soluble oxazoline-based crosslinking | 11.4 | parts by mass |
| agent | | |
| [EPOCROS (registered trademark) WS-700 | | |
| manufactured by Nippon Shokubai Co., | | |
| Ltd., solid content: 25 mass %] | | |
| Ammonium diphosphate (solid content: 35.0 | 0.9 | parts by mass |
| mass %) | | |
| Fluorine-based surfactant (solid content: | 1.0 | parts by mass |
| 2.0 mass %) | | |
| Distilled water | 61.3 | parts by mass |

### Comparative Example 4

A solar cell rear surface protective sheet was produced in the same manner as in Example 1 except that the thickness of the first resin layer in Example 1 was changed to 0.8 μm.

### Comparative Example 5

A solar cell rear surface protective sheet was produced in the same manner as in Example 1 except that the first resin layer in Example 1 was not formed.

### Comparative Example 6

A solar cell rear surface protective sheet was produced in the same manner as in Example 1 except that the second resin layer in Example 1 was not formed.

[Evaluation]

The following evaluations were carried out on the solar cell rear surface protective sheet produced in each of the examples and the comparative examples. The evaluation results are shown in Table 1.

<Modulus of Elasticity of Resin Layer>

The modulus of elasticity of each of the first resin layer and the second resin layer was measured as follows.

A resin layer forming composition was applied to a polyethylene terephthalate (PET) film (CERAPEEL (registered trademark) manufactured by Toray Industries, Inc.) treated by a release agent so as to cause the thickness thereof after being dried to reach 15 μm, and the resultant was dried at 170° C. for two minutes, thereby forming a resin layer (B) on the PET film.

The resin layer was cut into a size of 3 cm×5 mm, and the resin layer was peeled away from the PET film.

A tensile test for the resin layer (B) was conducted on the obtained resin layer using a tensile tester (TENSILON manufactured by A&D Company) in an environment with a temperature of 23.0° C. and a relative humidity of 50.0% at a rate of 50 mm/min, and the modulus of elasticity thereof was measured.

<Weather Resistance>

Weather resistance (wet heat stability) was evaluated according to the following standard by measuring an elongation at break retention half-life in the following method.

—Elongation at Break Retention Half-Life—

A preservation treatment (heating treatment) was carried out on the obtained solar cell rear surface protective sheet under conditions with a temperature of 120° C. and a relative humidity of 100%, and a preservation time (elongation at break retention half-life) for which the elongation at break (%) of the solar cell rear surface protective sheet after the preservation treatment was reduced to 50% of the elongation at break (%) of the solar cell rear surface protective sheet before the preservation treatment was measured.

A longer elongation at break retention half-life indicates better wet heat stability of the solar cell rear surface protective sheet.

—Evaluation Standard—

5: An elongation at break half-like time is 100 hours or longer.

4: An elongation at break half-like time is 90 hours or longer and shorter than 100 hours.

3: An elongation at break half-like time is 80 hours or longer and shorter than 90 hours.

2: An elongation at break half-like time is 70 hours or longer and shorter than 80 hours.

1: An elongation at break half-like time is shorter than 70 hours.

<EVA Adhesion Test>

The solar cell rear surface protective sheet obtained in each of the examples was cut into 1.0 cm (TD direction)×30 cm (MD direction). Next, two EVA films (Hangzhou, F806) were laminated on a glass plate having a size of 20 cm×20 cm×0.3 cm in thickness.

At a distance of 10 cm to 20 cm from one end portion of the glass plate on which the EVA films were laminated, a polyethylene terephthalate (PET) film (CERAPEEL (registered trademark) manufactured by Toray Industries, Inc.) treated with a release agent was laminated, the other end portion and an end portion in the MD direction of the solar cell rear surface protective sheet were aligned with each other and the solar cell rear surface protective sheet was placed so as to cause the second resin layer (C) to come into contact with the EVA films, and the resultant was laminated using a vacuum laminator (LAMINATOR 0505S) manufactured by Nisshinbo Mechatronics Inc. under conditions with a temperature of 145° C., evacuation for 4 minutes, and pressurization for 10 minutes.

(Adhesion after Preservation at 120° C. for 30 Hours)

The solar cell rear surface protective sheet attached to the EVA as described above was adjusted in humidity for 24 hours or longer under conditions with a temperature of 23° C. and a relative humidity of 50%, and was thereafter preserved in a wet heat environment at 120° C. and 100 RH % for 30 hours.

A portion with a width of 10 mm in the sample produced above was pulled at 180° by TENSILON at a rate of 100 mm/min.

In addition, on the base of the following evaluation standard, breaking and adhesion of the white PET film were evaluated.

[Breaking]

—Evaluation Standard—

1: The white PET film was broken.

2: The white PET film was not broken.

[Adhesion]

—Evaluation Standard—

5: The stress is 80 N/10 mm or higher.

4: The stress is 65 N/10 mm or higher and lower than 80 N/10 mm.

3: The stress is 50 N/10 mm or higher and lower than 65 N/10 mm.

2: The stress is 35 N/10 mm or higher and lower than 50 N/10 mm.

1: The stress is lower than 35 N/10 mm.

As the stress, the average value of stresses in a stress stable region with a peeling length of 3 to 4 cm was determined.

(Adhesion after Preservation at 120° C. for 60 Hours)

Even after a laminate of a back sheet with a notch, EVA, and a glass plate was preserved in a wet heat environment at 120° C. and 100 RH % for 60 hours, similarly, breaking and adhesion of the white PET film were evaluated.

In Table 1, the primary configurations and evaluation results of the base material film, the first resin layer, and the second resin layer are shown.

In Table 1, the ratio in brackets regarding the kind of the binder of the first resin layer or the second resin layer represents the mass ratio of the mixed resin. In addition, “−” in EVA adhesion test results means that breaking of the white PET film had occurred and adhesion could not be evaluated. “PVC” means the pigment volume concentration of inorganic particles.

TABLE 1

| | | | | First resin layer (B) | | | Second resin layer (C) | | | Film | | | | |
|---|---|---|---|---|---|---|---|---|---|---|---|---|---|---|
| | Base material film (A) | | | | Modu- | | | Modu- | | physical | | | | |
| | Heat | | | | lus | | | lus | | proper- | | | | |
| | setting | Inorganic | | Kind of | of | Film | Kind of | of | Film | ties | EVA adhesion test results | | | |
| | temper- | particles | | binder | elas- | thick- | binder | elas- | thick- | Weather | 120□/100%/30 h | | 120□/100%/60 h | |
| | ature | | Content | (mass | ticity | ness | (mass | ticity | ness | resis- | Break- | Adhe- | Break- | Adhe- |
| | [° C.] | Kind | [mass %] | ratio) | [GPa] | [μm] | ratio) | [MPa] | [μm] | tance | ing | sion | ing | sion |
| Exam- | 190 | Titanium | 4.4 | Acryl | 1.4 | 5 | Olefin + | 60 | 0.4 | 5 | 2 | 5 | 2 | 5 |
| ple 1 | | oxide | | | | | acryl | | | | | | | |
| | | | | | | | (80:20) | | | | | | | |
| Exam- | 190 | Titanium | 4.4 | Ester | 1.4 | 5 | Olefin + | 60 | 0.4 | 5 | 2 | 5 | 2 | 5 |
| ple 2 | | oxide | | | | | acryl | | | | | | | |
| | | | | | | | (80:20) | | | | | | | |
| Exam- | 190 | Titanium | 4.4 | Olefin + | 1.2 | 5 | Olefin + | 60 | 0.4 | 5 | 2 | 5 | 2 | 4 |
| ple 3 | | oxide | | acryl | | | acryl | | | | | | | |
| | | | | (20:80) | | | (80:20) | | | | | | | |
| Exam- | 190 | Titanium | 4.4 | Acryl | 1.8 | 5 | Olefin + | 60 | 0.4 | 5 | 2 | 5 | 2 | 5 |
| ple 4 | | oxide | | (titanium | | | acryl | | | | | | | |
| | | | | PVC 7%) | | | (80:20) | | | | | | | |
| Exam- | 190 | Titanium | 4.4 | Acryl | 1.4 | 1 | Olefin + | 60 | 0.4 | 5 | 2 | 4 | 2 | 4 |
| ple 5 | | oxide | | | | | acryl | | | | | | | |
| | | | | | | | (80:20) | | | | | | | |
| Exam- | 190 | Titanium | 4.4 | Acryl | 1.4 | 8 | Olefin + | 60 | 0.4 | 5 | 2 | 4 | 2 | 3 |
| ple 6 | | oxide | | | | | acryl | | | | | | | |
| | | | | | | | (80:20) | | | | | | | |
| Exam- | 190 | Titanium | 4.4 | Acryl | 1.4 | 10 | Olefin + | 60 | 0.4 | 5 | 2 | 3 | 2 | 3 |
| ple 7 | | oxide | | | | | acryl | | | | | | | |
| | | | | | | | (80:20) | | | | | | | |
| Exam- | 190 | Titanium | 4.4 | Acryl | 1.4 | 5 | Olefin + | 150 | 0.4 | 5 | 2 | 4 | 2 | 3 |
| ple 8 | | oxide | | | | | acryl | | | | | | | |
| | | | | | | | (60:40) | | | | | | | |
| Exam- | 190 | Titanium | 4.4 | Acryl | 1.4 | 5 | Olefin + | 180 | 0.4 | 5 | 2 | 3 | 2 | 3 |
| ple 9 | | oxide | | | | | acryl | | | | | | | |
| | | | | | | | (50:50) | | | | | | | |
| Exam- | 190 | Titanium | 4.4 | Acryl | 1.4 | 5 | Olefin + | 60 | 1.0 | 5 | 2 | 5 | 2 | 4 |
| ple 10 | | oxide | | | | | acryl | | | | | | | |
| | | | | | | | (80:20) | | | | | | | |
| Exam- | 190 | Titanium | 4.4 | Acryl | 1.4 | 5 | Olefin + | 60 | 1.5 | 5 | 2 | 4 | 2 | 3 |
| ple 11 | | oxide | | | | | acryl | | | | | | | |
| | | | | | | | (80:20) | | | | | | | |
| Exam- | 170 | Titanium | 4.4 | Acryl | 1.4 | 5 | Olefin + | 60 | 0.4 | 4 | 2 | 3 | 2 | 3 |
| ple 12 | | oxide | | | | | acryl | | | | | | | |
| | | | | | | | (80:20) | | | | | | | |
| Exam- | 180 | Titanium | 4.4 | Acryl | 1.4 | 5 | Olefin + | 60 | 0.4 | 5 | 2 | 4 | 2 | 3 |
| ple 13 | | oxide | | | | | acryl | | | | | | | |
| | | | | | | | (80:20) | | | | | | | |
| Exam- | 220 | Titanium | 4.4 | Acryl | 1.4 | 5 | Olefin + | 60 | 0.4 | 3 | 2 | 5 | 2 | 4 |
| ple 14 | | oxide | | | | | acryl | | | | | | | |
| | | | | | | | (80:20) | | | | | | | |
| Exam- | 230 | Titanium | 4.4 | Acryl | 1.4 | 5 | Olefin + | 60 | 0.4 | 2 | 2 | 5 | 2 | 5 |
| ple 15 | | oxide | | | | | acryl | | | | | | | |
| | | | | | | | (80:20) | | | | | | | |
| Compar- | 190 | Titanium | 4.4 | Olefin | 0.1 | 5 | Olefin + | 60 | 0.4 | 5 | 1 | — | 1 | — |
| ative | | oxide | | | | | acryl | | | | | | | |
| Exam- | | | | | | | (80:20) | | | | | | | |
| ple 1 | | | | | | | | | | | | | | |
| Compar- | 190 | Titanium | 4.4 | Olefin + | 1.0 | 5 | Olefin + | 60 | 0.4 | 5 | 1 | — | 1 | — |
| ative | | oxide | | acryl | | | acryl | | | | | | | |
| Exam- | | | | (50:50) | | | (80:20) | | | | | | | |
| ple 2 | | | | | | | | | | | | | | |
| Compar- | 190 | Titanium | 4.4 | Styrene- | 0.7 | 5 | Olefin + | 60 | 0.4 | 5 | 1 | — | 1 | — |
| ative | | oxide | | acryl | | | acryl | | | | | | | |
| Exam- | | | | copolymer | | | (80:20) | | | | | | | |
| ple 3 | | | | | | | | | | | | | | |
| Compar- | 190 | Titanium | 4.4 | Acryl | 1.4 | 0.8 | Olefin + | 60 | 0.4 | 5 | 1 | — | 1 | — |
| ative | | oxide | | | | | acryl | | | | | | | |
| Exam- | | | | | | | (80:20) | | | | | | | |
| ple 4 | | | | | | | | | | | | | | |
| Compar- | 190 | Titanium | 4.4 | — | — | — | Olefin + | 60 | 0.4 | 5 | 1 | — | 1 | — |
| ative | | oxide | | | | | acryl | | | | | | | |
| Exam- | | | | | | | (80:20) | | | | | | | |
| ple 5 | | | | | | | | | | | | | | |
| Compar- | 190 | Titanium | 4.4 | Acryl | 1.4 | 5 | — | — | — | 5 | 2 | 1 | 2 | 1 |
| ative | | oxide | | | | | | | | | | | | |
| Exam- | | | | | | | | | | | | | | |
| ple 6 | | | | | | | | | | | | | | |

(Formation of Weather-Resistant Layer)

On the side of the solar cell rear surface protective sheets produced in Examples 1 to 15, on which the first resin layer and the second resin layer of the white PET film were not formed, a coating layer (D) and a coating layer (E) were sequentially formed as weather-resistant layers by using a coating layer forming composition (D1) and a coating layer forming composition (E1) having the following compositions, thereby obtaining a solar cell rear surface protective sheet.

—Formation of Coating Layer (D)—

1. Preparation of Coating Layer Forming Composition

Individual components described below were mixed together, thereby preparing the coating layer forming composition (D1). As the “titanium oxide dispersion liquid” described below, the same titanium dioxide dispersion liquid as that adjusted in the resin layer (B) was used.

—Coating Layer Forming Composition (D1)—

| | | |
|---|---|---|
| Silicone-based compound | 381.7 | parts by mass |
| [CERANATE (registered trademark) WSA1070 | | |
| manufactured by DIC Corporation, | | |
| solid content: 38 mass %] | | |
| Polyoxyalkylene alkyl ether | 13.1 | parts by mass |
| [NAROACTY (registered trademark) CL-95 | | |
| manufactured by Sanyo Chemical | | |
| Industries, ltd., solid content: 1 mass %] | | |
| Water-soluble oxazoline-based crosslinking | 105.1 | parts by mass |
| agent | | |
| [EPOCROS (registered trademark) WS-700 | | |
| manufactured by Nippon Shokubai Co., | | |
| Ltd., solid content: 25 mass %] | | |
| Distilled water | 14.3 | parts by mass |
| Titanium oxide dispersion liquid (solid | 483.4 | parts by mass |
| content: 48 mass %) | | |

2. Formation of Coating Layer (D)

The obtained coating layer forming composition (D1) was applied onto the rear surface (surface on which the resin layer (B) was not formed) of the white PET film so that the amount of the binder applied reached 4.7 g/m² and the amount of titanium oxide applied reached 5.6 g/m² and the resultant was dried at 170° C. for two minutes, thereby forming a coating layer (D) having a thickness of 8 μm.

—Formation of Coating Layer (E)—

A coating liquid for the coating layer forming composition (E1) described below was applied to the surface of the coating layer (D) so that the amount of the binder applied reached 1.3 g/m², and the resultant was dried at 175° C. for two minutes, thereby forming a 1 μm-thick coating layer (E).

—Coating Layer Forming Composition (E1)—

| | | |
|---|---|---|
| Fluorine-based resin | 345.0 | parts by mass |
| [OBBLIGATO (registered trademark) SW0011F | | |
| manufactured by AGC Coat-Tech | | |
| Co., Ltd., solid content: 36 mass %] | | |
| Colloidal silica | 3.9 | parts by mass |
| [SNOWTEX (registered trademark) UP | | |
| manufactured by Nissan Chemical | | |
| Industries, Ltd., solid content: 20 | | |
| mass %] | | |
| Silane coupling agent | 78.5 | parts by mass |
| [TSL8340, Momentive Performance Materials | | |
| Inc., solid content: 1 mass %] | | |
| Synthetic wax | 207.0 | parts by mass |
| [CHEMIPAL (registered trademark) W950 | | |
| manufactured by Mitsui Chemicals, Inc., | | |
| solid content: 5 mass %] | | |
| Polyoxyalkylene alkyl ether | 60.0 | parts by mass |
| [NAROACTY (registered trademark) CL-95 | | |
| manufactured by Sanyo Chemical | | |
| Industries, ltd., solid content: 1 mass %] | | |
| Carbodiimide compound | 62.3 | parts by mass |
| [CARBODILITE (registered trademark) | | |
| V-02-L2 manufactured by Nisshinbo | | |
| Chemical Inc., solid content: 20 mass %] | | |
| Distilled water | 242.8 | parts by mass |

### Examples 16 to 30

<Production of Solar Cell Module>

Using the solar cell rear surface protective sheets of Examples 1 to 15 after the formation of the weather-resistant layers, solar cell modules of Examples 16 to 30 were produced in the following method.

A 3.2 mm-thick reinforced glass plate (transparent base material), an EVA sheet (sealing material: SC50B manufactured by Mitsui Chemicals, Inc.), a crystalline solar cell (solar cell element), an EVA sheet (SC50B manufactured by Mitsui Chemicals, Inc.), and the solar cell rear surface protective sheet of any one of Examples 1 to 15 were superimposed in this order, and were hot-pressed using a vacuum laminator (vacuum laminator manufactured by Nisshinbo Mechatronics Inc.) such that the individual members and the EVA sheets were adhered. In this manner, solar cell modules were produced.

(Evaluation)

A power generation operation test was conducted on each of the solar cell modules of Examples 16 to 30 produced as above, and the solar cell module in any of the examples exhibited favorable power generation performance as a solar cell.

The entirety of the disclosure of Japanese Patent Application No. 2014-176475 filed on Aug. 29, 2014, is incorporated herein by reference.

Publications, patent applications, and technical standards described in this specification are incorporated herein by reference to the same degree as in a case where those publications, patent applications, and technical standards are individually described in detail.

What is claimed is:

1. A solar cell rear surface protective sheet comprising:
a base material film including a white polyester film and having a thickness of from 20 μm to 500 μm, a first resin layer having a modulus of tensile elasticity of 1.2 GPa or higher and 3.0 GPa or lower and a thickness of 1 μm or greater, and a second resin layer having a lower modulus of tensile elasticity than the first resin layer, which are laminated in this order.

2. The solar cell rear surface protective sheet according to claim 1,
wherein the thickness of the first resin layer is 8 μm or smaller.

3. The solar cell rear surface protective sheet according to claim 1,
wherein the modulus of tensile elasticity of the second resin layer is 150 MPa or lower.

4. The solar cell rear surface protective sheet according to claim 3,
wherein the second resin layer includes an olefin-based resin.

5. The solar cell rear surface protective sheet according to claim 4,
wherein a thickness of the second resin layer is 0.01 μm or greater and 1 μm or smaller.

6. The solar cell rear surface protective sheet according to claim 1,
wherein the first resin layer includes at least one of an acrylic resin or an ester-based resin.

7. The solar cell rear surface protective sheet according to claim 1,
wherein the white polyester film is a film produced through a heat setting process, and
a heat setting temperature in the heat setting process is 180° C. or higher and 220° C. or lower.

8. The solar cell rear surface protective sheet according to claim 1,
wherein the white polyester film includes inorganic particles as a whitening agent.

9. The solar cell rear surface protective sheet according to claim 8,
wherein a content of the inorganic particles included in the white polyester film is 0.1 mass % or more and 10 mass % or less.

10. The solar cell rear surface protective sheet according to claim 9,
wherein the inorganic particles included in the white polyester film are titanium oxide.

11. A solar cell module comprising:
an element structure portion which includes a solar cell element and a sealing material which seals the solar cell element;
a transparent substrate which is positioned on a side of the element structure portion on which sunlight is incident; and
the solar cell rear surface protective sheet according to claim 1, which is positioned on a side opposite to the side of the element structure portion on which the substrate is positioned, and has the second resin layer adhered to the sealing material.
